(19) United States
(12) Patent Application Publication
(10) Pub. No.: US 2025/0015097 A1
(43) Pub. Date: Jan. 9, 2025

(54) STRETCHABLE DISPLAY DEVICE AND METHOD FOR FABRICATING THE SAME

(71) Applicant: Samsung Display Co., LTD., Yongin-si (KR)

(72) Inventors: Jin Woo CHOI, Yongin-si (KR); Dae Ho SONG, Yongin-si (KR); Hyung Il JEON, Yongin-si (KR)

(21) Appl. No.: 18/760,857

(22) Filed: Jul. 1, 2024

(30) Foreign Application Priority Data
Jul. 4, 2023 (KR) 10-2023-0086323

(51) Int. Cl. H01L 27/12; H01L 25/16

(52) U.S. Cl. CPC H01L 27/1248; H01L 25/167; H01L 27/1259; H01L 27/124

(57) ABSTRACT

A stretchable display device and a method for fabricating the same is provided. A display device includes a substrate including a plurality of island patterns and a first bridge pattern connecting a first island pattern and a second island pattern adjacent to each other from among the plurality of island patterns, and a plurality of pixel light emitting chips, a pixel light emitting chip from among the plurality of pixel light emitting chips located on a corresponding island pattern from among the plurality of island patterns. Each of the plurality of pixel light emitting chips includes a transistor layer including a plurality of transistors, and a light emitting element layer on the transistor layer, and including a plurality of light emitting elements.

### CROSS-REFERENCE TO RELATED APPLICATION

The present application claims priority to and the benefit of Korean Patent Application No. 10-2023-0086323, filed on Jul. 4, 2023, in the Korean Intellectual Property Office, the entire disclosure of which is incorporated by reference herein.

### BACKGROUND

### 1. Field

One or more embodiments of the present disclosure relate to a stretchable display device and a method for fabricating the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device include an organic light emitting display device composed of organic light emitting elements, an inorganic light emitting display device composed of inorganic light emitting elements such as inorganic semiconductors, and a micro light emitting display device composed of micro light emitting elements.

Recently, a light emitting display device has been developed as a display device that can be vertically and/or horizontally stretched. The stretchable display device includes non-stretching portions in which pixel circuits are respectively disposed, and stretching portions connecting adjacent non-stretching portions to each other. Because the stretching portions and the non-stretching portions are distinguished, it is difficult to enlarge the area of the non-stretching portions, which makes it difficult to manufacture a stretchable display device with a high degree of pixel integration.

### SUMMARY

Aspects and features of embodiments of the present disclosure provide a stretchable display device with a high degree of pixel integration.

Aspects and features of embodiments of the present disclosure provide a method for fabricating a stretchable display device with a high degree of pixel integration.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device. The display device includes a substrate including a plurality of island patterns and a first bridge pattern connecting a first island pattern and a second island pattern adjacent to each other from among the plurality of island patterns, and a plurality of pixel light emitting chips, each of the plurality of pixel light emitting chips located on a corresponding island pattern from among the plurality of island patterns. Each of the plurality of pixel light emitting chips includes a transistor layer including a plurality of transistors, and a light emitting element layer on the transistor layer, and including a plurality of light emitting elements.

The plurality of pixel light emitting chips may correspond one-to-one to the plurality of island patterns.

The plurality of light emitting elements may include a light emitting element of a first pixel, a light emitting element of a second pixel, and a light emitting element of a third pixel. Each of the plurality of pixel light emitting chips may further include a first light conversion layer on the light emitting element of the first pixel and configured to convert light emitted from the light emitting element of the first pixel into light of a first wavelength band, a second light conversion layer on the light emitting element of the second pixel and configured to convert light emitted from the light emitting element of the second pixel into light of a second wavelength band, and a light transmitting layer on the light emitting element of the third pixel and configured to transmit light emitted from the light emitting element of the third pixel.

The display device may further include a first scan line on the first island pattern, the second island pattern, and the first bridge pattern, and a first scan pad connected to the first scan line and located on the first island pattern.

One of the plurality of pixel light emitting chips may further include a first chip pad electrically connected to the first scan pad.

The first scan pad and the first chip pad may overlap each other in a third direction, the third direction being a thickness direction of the substrate.

The transistor layer may include a first insulating layer on the first chip pad, a gate electrode of a first transistor from among the plurality of transistors on the first insulating layer and electrically connected to the first chip pad, a second insulating layer on the gate electrode of the first transistor, an active layer of the first transistor on the second insulating layer, and a third insulating layer on the active layer of the first transistor.

The plurality of light emitting elements of the light emitting element layer may be on the third insulating layer.

The display device may further include a first data line on the first island pattern, the second island pattern, and the first bridge pattern, and a first data pad connected to the first data line and located on the first island pattern.

One of the plurality of pixel light emitting chips may further include a second chip pad electrically connected to the first data pad.

The first data pad and the second chip pad may overlap each other in a third direction, the third direction being a thickness direction of the substrate.

The transistor layer may include a first insulating layer on the second chip pad, a gate electrode of a second transistor from among the plurality of transistors and a first connection electrode on the first insulating layer, a second insulating layer on the first connection electrode and the gate electrode of the second transistor, an active layer of the second transistor on the second insulating layer and connected to the first connection electrode through a contact hole penetrating the second insulating layer, and a third insulating layer on the active layer of the second transistor.

The plurality of light emitting elements of the light emitting element layer may be located on the third insulating layer.

The display device may further include a first power line on the first island pattern, the second island pattern, and the first bridge pattern, and a first power pad connected to the first power line and located on the first island pattern.

One of the plurality of pixel light emitting chips may further include a third chip pad electrically connected to the first power pad.

The transistor layer may include a first insulating layer on the third chip pad, a second connection electrode on the first insulating layer and connected to the third chip pad through a contact hole penetrating the first insulating layer, a second insulating layer on the second connection electrode, and a third connection electrode on the second insulating layer and connected to the second connection electrode through a contact hole penetrating the second insulating layer.

Each of the plurality of light emitting elements of the light emitting element layer may include a first semiconductor layer, an active layer, and a second semiconductor layer sequentially stacked. The third connection electrode may be electrically connected to the second semiconductor layer.

According to one or more embodiments of the present disclosure, there is provided a display device that includes a substrate including a first island pattern and a second island pattern adjacent to each other in a first direction, a third island pattern adjacent to the first island pattern in a second direction crossing the first direction, a first bridge pattern connecting the first island pattern and the second island pattern, and a second bridge pattern connecting the first island pattern and the third island pattern in the second direction, a first scan line located on the first island pattern and the first bridge pattern, and configured to receive a first scan signal, a first data line located on the first island pattern and the second bridge pattern, and configured to receive a first data voltage, a first scan pad located on the first island pattern, and connected to the first scan line, a first data pad located on the first island pattern, and connected to the first data line, and a pixel light emitting chip including a pad layer including a first chip pad electrically connected to the first scan pad and a second chip pad electrically connected to the first data pad, a transistor layer including a plurality of transistors located on the pad layer, and a light emitting element layer located on the transistor layer and including a plurality of light emitting elements.

According to one or more embodiments of the present disclosure, there is provided a method for fabricating a display device that includes forming a plurality of pixel light emitting chips, each of the plurality of pixel light emitting chips including a chip pad layer including a plurality of chip pads, a transistor layer located on the chip pad layer, and a light emitting element layer located on the transistor layer, forming a substrate including a plurality of island patterns and bridge patterns each connecting island patterns adjacent to each other from among the plurality of island patterns, and attaching the plurality of pixel light emitting chips to the plurality of island patterns, respectively.

The forming of the plurality of pixel light emitting chips includes sequentially forming a second semiconductor material layer, an active material layer, and a first semiconductor material layer on a semiconductor substrate, forming a first insulating layer on the first semiconductor material layer, and forming active patterns of transistors on the first insulating layer, forming a second insulating layer on the active patterns, and forming gate electrodes of the transistors on the second insulating layer, forming a third insulating layer on the gate electrodes, and forming the plurality of chip pads on the third insulating layer; removing the semiconductor substrate, and patterning the second semiconductor material layer, the active material layer, and the first semiconductor material layer to form the light emitting element layer including a plurality of light emitting elements.

According to the aforementioned and other embodiments of the present disclosure, a pixel light emitting chip may be a chip in which a pixel layer including a plurality of transistors, a light emitting element layer including a plurality of light emitting elements, and an optical layer including a plurality of light conversion layers are integrated. Therefore, even if the area of an island pattern corresponding to the non-stretching portion is reduced in order to implement a high-resolution display device, a plurality of pixel light emitting chips only need to be respectively attached on a plurality of island patterns. Thus, it is possible to provide a stretchable display device with a high degree of pixel integration.

### BRIEF DESCRIPTION OF THE DRAWINGS

The above and other embodiments and features of the present disclosure will become more apparent by describing embodiments thereof with reference to the attached drawings, in which:

FIGS. 1 and 2 are perspective views illustrating a stretchable display device according to one or more embodiments;

FIG. 3 is a block diagram illustrating a stretchable display device according to one or more embodiments;

FIG. 4 is an equivalent circuit diagram illustrating a first pixel according to one or more embodiments;

FIG. 5 is a layout diagram illustrating a display panel, a display circuit board, and a display driving circuit according to one or more embodiments;

FIG. 6 is a layout diagram showing a display area of the display panel of FIG. 5;

FIG. 7 is a perspective view illustrating a first island pattern and a pixel light emitting chip in an area A of FIG. 6;

FIG. 8 is an exploded perspective view illustrating a first island pattern and a pixel light emitting chip in the area A of FIG. 6;

FIG. 9 is a layout diagram illustrating one example of a plurality of scan lines, a plurality of data lines, a plurality of power lines, a plurality of bridges, and a plurality of pixel pads in the area A of FIG. 6;

FIG. 10 is a layout diagram illustrating a first island pattern and first to third light exit areas of a pixel light emitting chip in the area A of FIG. 6;

FIG. 11 is a cross-sectional view showing an example of a first island pattern and a pixel light emitting chip taken along the line Z-Z′ of FIGS. 9 and 10;

FIG. 12 is a cross-sectional view showing an example of a first island pattern and a pixel light emitting chip taken along the line Y-Y′ of FIGS. 9 and 10;

FIG. 13 is a cross-sectional view showing an example of a first island pattern and a pixel light emitting chip taken along the line X-X′ of FIGS. 9 and 10;

FIG. 14 is a flowchart illustrating a method for fabricating a stretchable display device according to one or more embodiments;

FIGS. 15 and 16 are an exploded perspective view and a perspective view illustrating a method for fabricating a stretchable display device according to one or more embodiments, respectively;

FIG. 17 is a flowchart showing an example of step S100 of FIG. 14 in detail; and

FIGS. 18 to 26 are cross-sectional views for describing an example of step S100 of FIG. 14.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

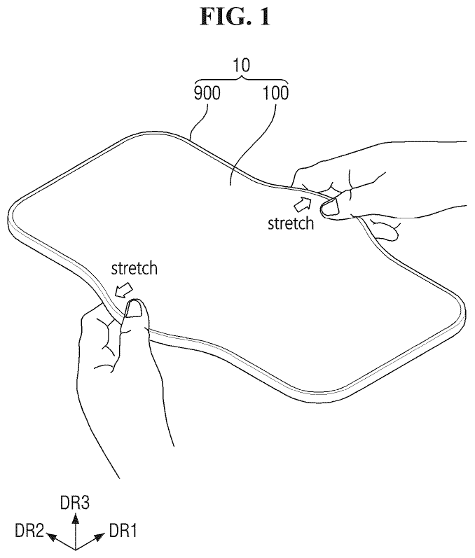

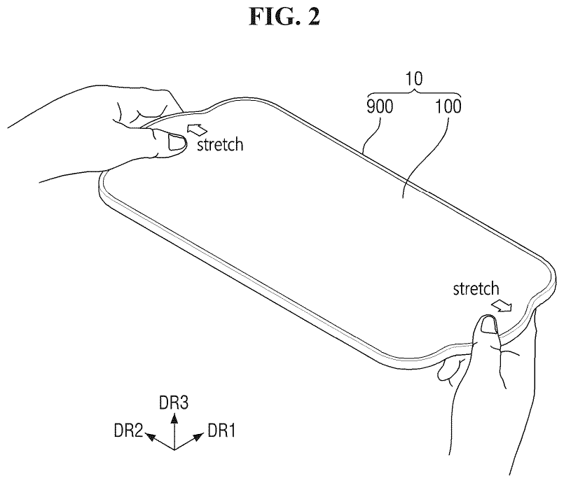

FIGS. 1 and 2 are perspective views illustrating a stretchable display device according to one or more embodiments.

Referring to FIGS. 1 and 2, a display device 10 is a device for displaying a moving image or a still image. The display device 10 may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may have a short side in the first direction DR1 and a long side in the second direction DR2 crossing the first direction DR1. A corner where the short side of the first direction DR1 and the long side of the second direction DR2 meet may be rounded to have a certain curvature, but the present disclosure is not limited thereto. The corner of the display device 10 may be right-angled. The planar shape of a display panel 100 may be similar to a quadrangle. However, the present disclosure is not limited thereto, and the display device 10 may be formed in a shape similar to another polygon, a circular shape or an elliptical shape. The display panel 100 may be formed to be flat, but is not limited thereto.

The display device 10 includes the display panel 100 and a lower cover 900.

The display panel 100 may be a light emitting display panel including a light emitting element. For example, the display panel 100 may be an organic light emitting display panel including an organic light emitting diode (OLED) having an organic light emitting layer, a micro light emitting diode (micro LED) display panel including a micro LED made of an inorganic material, or a quantum dot light emitting display panel using a quantum dot light emitting diode including a quantum dot light emitting layer. Hereinafter, the display panel 100 will be mainly described as being a micro LED display panel including a micro LED.

The lower cover 900 may form an external appearance of the bottom surface of the display device 10. The lower cover 900 may cover the side surface and the bottom surface of the display panel 100. The lower cover 900 may include plastic, metal, or both plastic and metal.

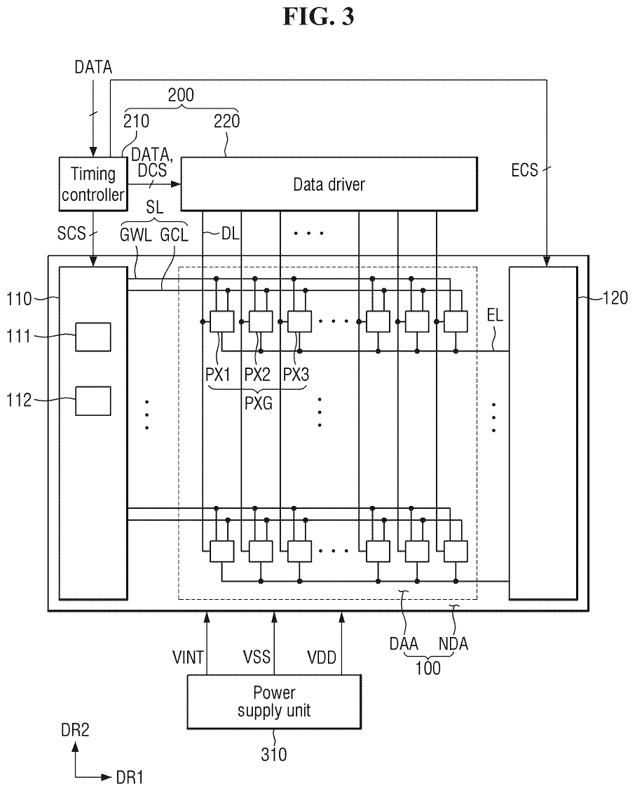

FIG. 1 illustrates the stretchable display device 10 that is stretched in the first direction DR1. When the left side of the stretchable display device 10 is held with one hand and stretched leftwards, while the right side of the stretchable display device 10 is held with the other hand and stretched rightwards, the stretchable display device 10 may be stretched in the first direction DR1. When the display device 10 is stretched in the first direction DR1, the maximum length of a display area DAA (e.g., see FIG. 3) in the first direction DR1 may increase. That is, when the display device 10 is stretched in the first direction DR1, the area of the display area DAA may increase.

FIG. 2 illustrates the stretchable display device 10 that is stretched in the second direction DR2. When the upper side of the stretchable display device 10 is held with one hand and stretched upwards, while the lower side of the stretchable display device 10 is held with the other hand and stretched downwards, the stretchable display device 10 may be stretched in the second direction DR2. When the stretchable display device 10 is stretched in the second direction DR2, the maximum length of the display area DAA in the second direction DR2 may increase. That is, when the stretchable display device 10 is stretched in the second direction DR2, the area of the display area DAA may increase.

In summary, the stretching of the display device 10 is performed by an external force, and when the external force is removed, it may contract and return to its original state. FIGS. 1 and 2 illustrate that the stretchable display device 10 is stretched in the first direction DR1 and the second direction DR2, but the present disclosure is not limited thereto. The stretchable display device 10 may also be stretched in a diagonal direction between the first direction DR1 and the second direction DR2.

FIG. 3 is a block diagram illustrating a stretchable display device according to one or more embodiments.

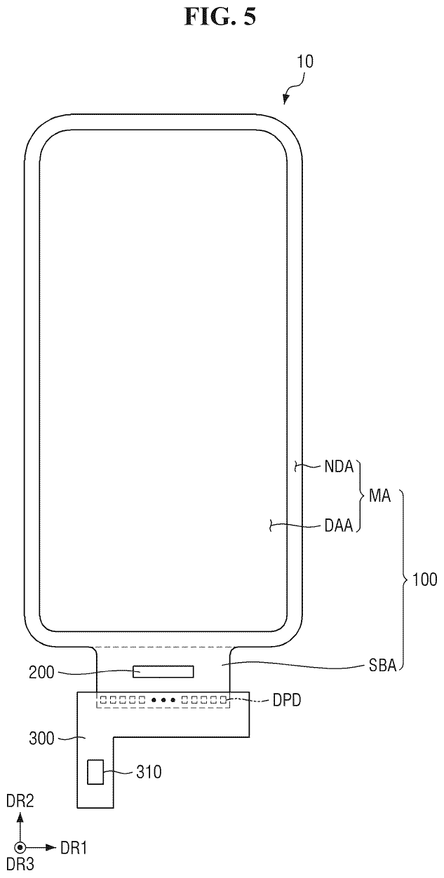

Referring to FIG. 3, the display device 10 according to one or more embodiments includes the display panel 100, a display driving circuit 200, and a display circuit board 300 (e.g., see FIG. 5).

The display panel 100 includes a display area DAA configured to display an image and a non-display area NDA not configured to display an image.

The display area DAA includes a plurality of unit pixels PXG, a plurality of scan lines SL, a plurality of emission control lines EL, and a plurality of data lines DL.

Each of the plurality of unit pixels PXG includes a plurality of pixels PX1, PX2, and PX3. The unit pixel PXG refers to a group of minimum pixels PX1, PX2, and PX3 that can express color.

Each of the plurality of pixels PX1, PX2, and PX3 includes a light emitting element that emits light. The plurality of scan lines SL and the plurality of emission control lines EL may extend in the first direction DR1, while being arranged along the second direction DR2. The plurality of data lines DL may extend in the second direction DR2 and may be disposed along the first direction DR1. The plurality of scan lines SL include a plurality of write scan lines GWL and a plurality of control scan lines GCL.

Each of the plurality of pixels PX1, PX2, and PX3 may be connected to any one of the plurality of write scan lines GWL, any one of the plurality of control scan lines GCL, any one of the plurality of emission control lines EL, and at least any one of the plurality of data lines DL. Each of the plurality of pixels PX1, PX2, and PX3 may receive a data voltage of the data line DL in response to a write scan signal of the write scan line GWL, and emit light from the light emitting element according to the data voltage.

The non-display area NDA includes a scan driver 110 and an emission driver 120. Although it is illustrated in FIG. 3 that the scan driver 110 is disposed on the left side of the display area DAA and the emission driver 120 is disposed on the right side of the display area DAA, the present disclosure is not limited thereto. For example, the scan driver 110 and the emission driver 120 may be disposed on both the left side and the right side of the display area DAA.

The scan driver 110 includes a write scan signal output unit 111 and a control scan signal output unit 112. Each of the write scan signal output unit 111 and the control scan signal output unit 112 may receive a scan timing control signal SCS from a timing controller 210. The write scan signal output unit 111 may generate write scan signals in response to the scan timing control signal SCS of the timing controller 210 and sequentially output them to the write scan lines GWL. The control scan signal output unit 112 may generate control scan signals in response to the scan timing control signal SCS and sequentially output them to the control scan lines GCL.

The emission driver 120 may receive an emission timing control signal ECS from the timing controller 210. The emission driver 120 may generate emission control signals in response to the emission timing control signal ECS and sequentially output them to the emission control lines EL.

The display driving circuit 200 includes a timing controller 210 and a data driver 220.

The timing controller 210 may receive digital video data DATA and timing signals from the outside. The timing controller 210 may generate the scan timing control signal SCS, the emission timing control signal ECS, and a data timing control signal DCS for controlling the display panel 100 in response to the timing signals. The timing controller 210 may output the scan timing control signal SCS to a scan driver 110, and output the emission timing control signal ECS to the emission driver 120. The timing controller 210 may output digital video data DATA and the data timing control signal DCS to a data driver 220.

The data driver 220 may receive the digital video data DATA and the data timing control signal DCS from the timing controller 210. The data driver 220 converts the digital video data DATA into analog data voltages in response to the data timing control signal DCS, and outputs them to the data lines DL. Accordingly, the pixels PX1, PX2, and PX3 are selected by the write scan signal of the scan driver 110, and data voltages may be supplied to the selected pixels PX1, PX2, and PX3.

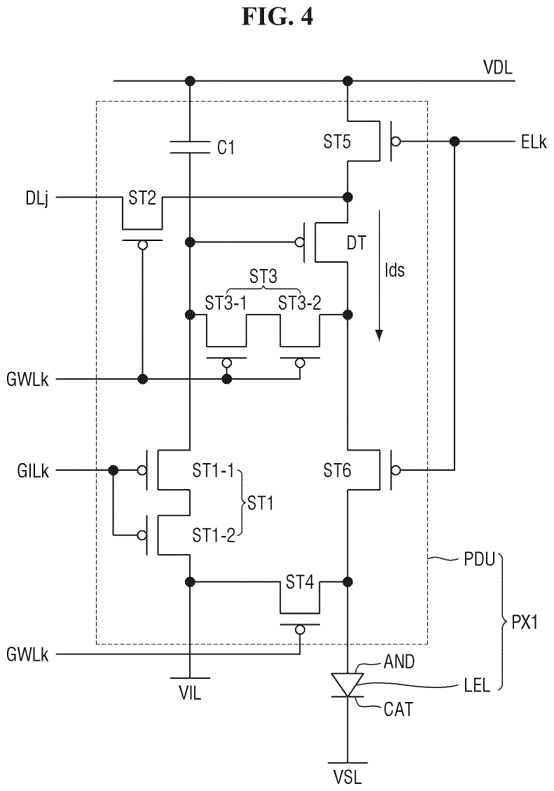

A power supply unit 310 in the display circuit board 300 may generate a plurality of panel power voltages by an external power voltage. For example, the power supply unit 310 may generate a first power voltage VSS, a second power voltage VDD, and a third power voltage VINT and supply them to the display panel 100. Description of the first power voltage VSS, the second power voltage VDD, and the third power voltage VINT will be provided later with reference to FIG. 4. The power supply unit 310 may be formed as an integrated circuit (IC).

FIG. 4 is an equivalent circuit diagram illustrating a first pixel according to one or more embodiments.

Referring to FIG. 4, the first pixel PX1 according to one or more embodiments may be connected to a k^{th} (k being a positive integer) initialization scan line GILk, a k^{th} write scan line GWLk, and a k^{th} emission line ELk. Also, the first pixel PX1 may be connected to a first power line VSL to which the first power voltage VSS is supplied, a second power line VDL to which the second power voltage VDD is applied, and a third power line VIL to which the third power voltage VINT is applied.

The first pixel PX1 includes at least one light emitting element LEL and a pixel circuit unit PDU. The pixel circuit unit PDU includes a driving transistor DT, at least one switch element, and a capacitor C1. The at least one switch element may include first to sixth transistors ST1, ST2, ST3, ST4, ST5, and ST6, but the present disclosure is not limited thereto.

The driving transistor DT may include a gate electrode, a first electrode, and a second electrode. The driving transistor DT controls a drain-source current Ids (hereinafter, referred to as “driving current”) flowing between the first electrode and the second electrode of the driving transistor DT according to a data voltage applied to the gate electrode of the driving transistor DT.

The light emitting element LEL emits light in response to the driving current Ids. As the driving current Ids increases, the amount of light emitted from the light emitting element LEL may increase.

The light emitting element LEL may be an organic light emitting diode (OLED) including an organic light emitting layer disposed between an anode electrode AND and a cathode electrode CAT. Alternatively, the light emitting element LEL may be a micro light emitting diode including a semiconductor made of an inorganic material disposed between the anode electrode AND and the cathode electrode CAT. Alternatively, the light emitting element LEL may be a quantum dot light emitting element including a quantum dot light emitting layer disposed between the anode electrode AND and the cathode electrode CAT.

The anode electrode AND of the light emitting element LEL may be connected to a first electrode of the fourth transistor ST4 and a second electrode of the sixth transistor ST6, and the cathode electrode CAT may be connected to the first power line VSL.

The first transistor ST1 is turned on by an initialization scan signal of the k^{th} initialization scan line GILk to connect the gate electrode of the driving transistor DT to the third power line VIL. Accordingly, the third power voltage VINT of the third power line VIL may be applied to the gate electrode of the driving transistor DT. The first transistor ST1 may include a plurality of sub-transistors ST1-1 and ST1-2 to prevent current leakage of the gate electrode of the driving transistor DT.

The second transistor ST2 is turned on by the write scan signal of the k^{th} write scan line GWLk to connect the first electrode of the driving transistor DT to a j^{th} (j being a positive integer) data line DLj. Accordingly, the data voltage of the j^{th} data line DLj may be applied to the first electrode of the driving transistor DT.

The third transistor ST3 is turned on by the write scan signal of the k^{th} write scan line GWLk to connect the gate electrode of the driving transistor DT to the second electrode thereof. When the gate electrode of the driving transistor DT is connected to the second electrode thereof, the driving transistor DT is driven as a diode (e.g., the driving transistor DT is diode-connected). The third transistor ST3 may include a plurality of sub-transistors ST3-1 and ST3-2 to prevent current leakage of the gate electrode of the driving transistor DT.

The fourth transistor ST4 is turned on by the write scan signal of the k^{th} write scan line GWLk to connect the anode electrode AND of the light emitting element LEL to the third power line VIL. The third power voltage VINT of the third power line VIL may be applied to the anode electrode AND of the light emitting element LEL.

The fifth transistor ST5 is turned on by the emission control signal of a k^{th} emission line ELk to connect the first electrode of the driving transistor DT to the second power line VDL. The sixth transistor ST6 is disposed between the second electrode of the driving transistor DT and the anode electrode AND of the light emitting element LEL. The sixth transistor ST6 is turned on by the emission control signal of the k^{th} emission line ELk to connect the second electrode of the driving transistor DT to the anode electrode AND of the light emitting element LEL. When both the fifth transistor ST5 and the sixth transistor ST6 are turned on, the driving current Ids of the driving transistor DT according to the data voltage applied to the gate electrode of the driving transistor DT may flow to the light emitting element LEL.

The capacitor C1 is formed between the gate electrode of the driving transistor DT and the second power line VDL. The first capacitor electrode of the capacitor C1 may be connected to the gate electrode of the driving transistor DT, and the second capacitor electrode thereof may be connected to the second power line VDL.

When the first electrode of each of the driving transistor DT and the first to sixth transistors ST1 to ST6 is a source electrode, the second electrode thereof may be a drain electrode. Alternatively, when the first electrode of each of the driving transistor DT and the first to sixth transistors ST1 to ST6 is a drain electrode, the second electrode thereof may be a source electrode.

An active layer of each of the driving transistor DT and the first to sixth transistors ST1 to ST6 may be formed of at least one of polysilicon, amorphous silicon, and/or an oxide semiconductor. In FIG. 4, the first to sixth transistors ST1 to ST6, and the driving transistor DT have been mainly described as being formed of a P-type MOSFET, but the present disclosure is not limited thereto. For example, the first to sixth transistors ST1 to ST6, and the driving transistor DT may be formed as an N-type MOSFET. Alternatively, some of the first to sixth transistors ST1, ST2, ST3, ST4, ST5, and ST6 may be formed as P-type MOSFETs, while the remaining transistors may be formed as N-type MOSFETs.

Because the equivalent circuit diagram of the second pixel PX2 and the equivalent circuit diagram of the third pixel PX3 may be substantially the same as the equivalent circuit diagram of the first pixel PX1 described in conjunction with FIG. 4, description of the equivalent circuit diagrams of the second and third pixels PX2 and PX3 will be omitted.

FIG. 5 is a layout diagram illustrating a display panel, a display circuit board, and a display driving circuit according to one or more embodiments.

Referring to FIG. 5, the display panel 100 according to one or more embodiments include a main region MA and a sub-region SBA protruding from one side of the main region MA.

The main region MA may include the display area DAA displaying an image and the non-display area NDA that is a peripheral area of the display area DAA. The display area DAA may occupy most of the main region MA. The display area DAA may be disposed at the center of the main region MA. The non-display area NDA may be an area outside the display area DAA and around the display area DAA along an edge or periphery of the display area DAA. In other words, the non-display area NDA may be defined as an edge area of the display panel 100.

The sub-region SBA may protrude in the second direction DR2 from one side of the main region MA. For example, one side of the main region MA may be a lower side of the main region MA. As illustrated in FIG. 5, the length of the sub-region SBA in the first direction DR1 may be smaller than the length of the main region MA in the first direction DR1, and the length of the sub-region SBA in the second direction DR2 may be smaller than the length of the main region MA in the second direction DR2, but the present disclosure is not limited thereto.

The sub-region SBA may be bent (e.g., as shown in FIG. 5) and may be disposed under the display panel 100. In this case, the sub-region SBA may overlap the main region MA of the display panel 100 in the third direction DR3.

Display pads DPD may be disposed at one side edge of the sub-region SBA. One side edge of the sub-region SBA may be a lower side edge of the sub-region SBA.

The display circuit board 300 may be attached to the display pads DPD of the sub-region SBA. The display circuit board 300 may be attached to the display pads DPD of the sub-region SBA by using a conductive adhesive member such as an anisotropic conductive film or an anisotropic conductive paste. The display circuit board 300 may be a flexible printed circuit board (FPCB) which is bendable, a rigid printed circuit board (PCB) which is solid to be hardly bent, or a composite printed circuit board having both of the rigid printed circuit board and the flexible printed circuit board. The power supply unit 310 may be disposed on the display circuit board 300.

The display driving circuit 200 may be disposed in the sub-region SBA of the display panel 100. The display driving circuit 200 may receive the digital video data DATA and the timing signals, and may generate and output the scan timing control signal SCS, the emission timing control signal ECS, and the data timing control signal DCS for driving the display panel 100. The display driving circuit 200 may be formed as an integrated circuit (IC).

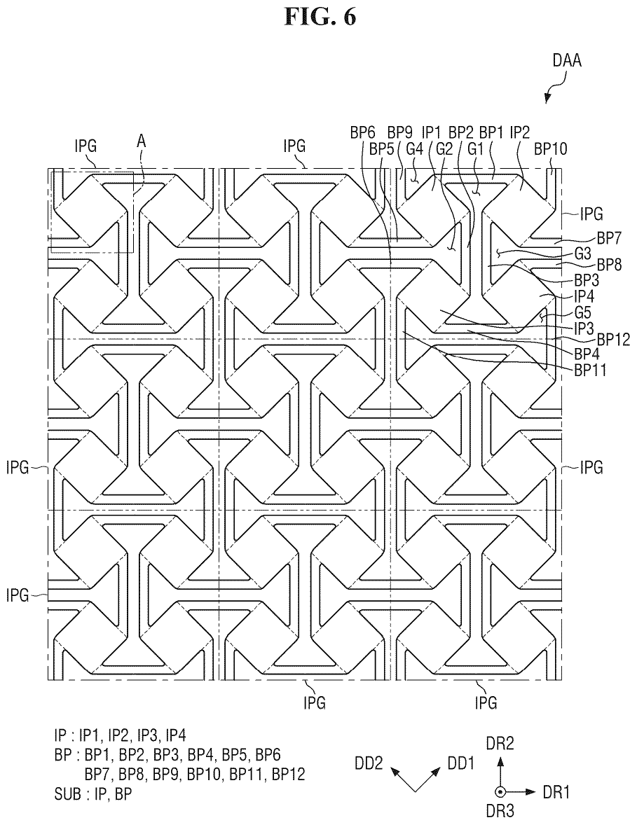

FIG. 6 is a layout diagram showing a display area of the display panel of FIG. 5.

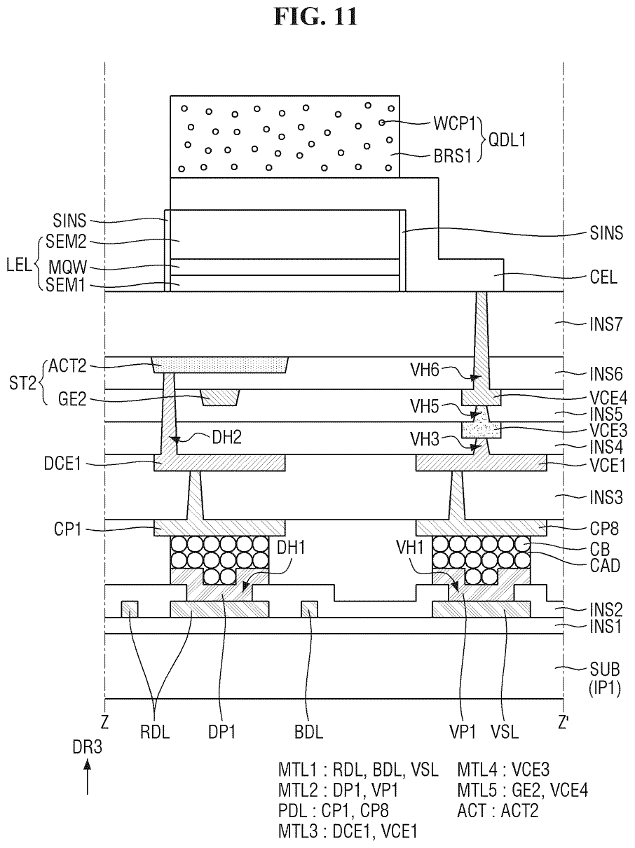

Referring to FIG. 6, a substrate SUB (e.g., see FIG. 11) of the display panel 100 may include a plurality of island patterns IP and a plurality of bridge patterns BP to reduce a stretching stress that is applied to the substrate SUB in the stretching direction when the display device 10 is stretched.

Each of the plurality of island patterns IP may have a rectangular, rhombic, and/or square shape in a plan view. Each of the plurality of island patterns IP may have a first side and a second side extending in a first diagonal direction DD1 that is a direction between the first and second directions DR1 and DR2, and a third side and a fourth side extending in a second diagonal direction DD2 that is orthogonal to the first diagonal direction DD1. Each of the plurality of island patterns IP may be connected to four bridge patterns BP. For example, each of the plurality of island patterns IP may be connected to the bridge patterns BP at respective vertices thereof.

The plurality of island patterns IP may include a first island pattern IP1, a second island pattern IP2, a third island pattern IP3, and a fourth island pattern IP4. The first island pattern IP1, the second island pattern IP2, the third island pattern IP3, and the fourth island pattern IP4 may be defined as one island pattern group IPG.

The first island pattern IP1 and the second island pattern IP2 may be disposed adjacent to each other in the first direction DR1, and the third island pattern IP3 and the fourth island pattern IP4 may be disposed adjacent to each other in the first direction DR1. The first island pattern IP1 and the third island pattern IP3 may be disposed adjacent to each other in the second direction DR2, and the second island pattern IP2 and the fourth island pattern IP4 may be disposed adjacent to each other in the second direction DR2.

The plurality of bridge patterns BP may include first to twelfth bridge patterns BP1 to BP12. The plurality of bridge patterns BP may extend in the first direction DR1 or the second direction DR2.

Each of the first bridge pattern BP1, the second bridge pattern BP2, the third bridge pattern BP3, and the fourth bridge pattern BP4 refers to a pattern connecting island patterns adjacent in the first direction DR1 or the second direction DR2 in the island pattern group IPG. The first bridge pattern BP1 may connect the first island pattern IP1 and the second island pattern IP2 of the island pattern group IPG. The second bridge pattern BP2 may connect the first island pattern IP1 and the third island pattern IP3 of the island pattern group IPG. The third bridge pattern BP3 may connect the second island pattern IP2 and the fourth island pattern IP4 of the island pattern group IPG. The fourth bridge pattern BP4 may connect the third island pattern IP3 and the fourth island pattern IP4 of the island pattern group IPG.

Each of the fifth bridge pattern BP5, the sixth bridge pattern BP6, the seventh bridge pattern BP7, and the eighth bridge pattern BP8 refers to a pattern connecting island patterns of the island pattern groups IPG adjacent to each other in the first direction DR1. The fifth bridge pattern BP5 may connect the first island pattern IP1 of the island pattern group IPG to the second island pattern IP2 of another island pattern group IPG adjacent thereto in the first direction DR1 (for example, on the left side). The sixth bridge pattern BP6 may connect the third island pattern IP3 of the island pattern group IPG to the fourth island pattern IP4 of another island pattern group IPG adjacent thereto in the first direction DR1 (for example, on the left side). The seventh bridge pattern BP7 may connect the second island pattern IP2 of the island pattern group IPG to the first island pattern IP1 of another island pattern group IPG adjacent thereto in the first direction DR1 (for example, on the right side). The eighth bridge pattern BP8 may connect the fourth island pattern IP4 of the island pattern group IPG to the third island pattern IP3 of another island pattern group IPG adjacent thereto in the first direction DR1 (for example, on the right side).

Each of the ninth bridge pattern BP9, the tenth bridge pattern BP10, the eleventh bridge pattern BP11, and the twelfth bridge pattern BP12 refers to a pattern connecting island patterns of the island pattern groups IPGs adjacent to each other in the second direction DR2. The ninth bridge pattern BP9 may connect the first island pattern IP1 of the island pattern group IPG to the third island pattern IP3 of another island pattern group IPG adjacent thereto in the second direction DR2 (for example, on the upper side). The tenth bridge pattern BP10 may connect the second island pattern IP2 of the island pattern group IPG to the fourth island pattern IP4 of another island pattern group IPG adjacent thereto in the second direction DR2 (for example, on the upper side). The eleventh bridge pattern BP11 may connect the third island pattern IP3 of the island pattern group IPG to the first island pattern IP1 of another island pattern group IPG adjacent thereto in the second direction DR2 (for example, on the lower side). The twelfth bridge pattern BP12 may connect the fourth island pattern IP4 of the island pattern group IPG to the second island pattern IP2 of another island pattern group IPG adjacent thereto in the second direction DR2 (for example, on the lower side).

First to fifth gaps G1 to G5 may exist in the island pattern group IPG.

The first gap G1 may be defined by the first island pattern IP1, the first bridge pattern BP1, the second island pattern IP2, the third bridge pattern BP3, the fourth island pattern IP4, the fourth bridge pattern BP4, the third island pattern IP3, and the second bridge pattern BP2.

The second gap G2 may be defined by the fifth bridge pattern BP5, the first island pattern IP1, the second bridge pattern BP2, the third island pattern IP3, and the sixth bridge pattern BP6. The third gap G3 may be defined by the seventh bridge pattern BP7, the second island pattern IP2, the third bridge pattern BP3, the fourth island pattern IP4, and the eighth bridge pattern BP8. The second gap G2 of the island pattern group IPG may be connected to the third gap G3 of another island pattern group IPG adjacent thereto in the first direction DR1 (for example, on the left side). The third gap G3 of the island pattern group IPG may be connected to the second gap G2 of another island pattern group IPG adjacent thereto in the first direction DR1 (for example, on the right side).

The fourth gap G4 may be defined by the ninth bridge pattern BP9, the first island pattern IP1, the first bridge pattern BP1, the second island pattern IP2, and the tenth bridge pattern BP10. The fifth gap G5 may be defined by the eleventh bridge pattern BP11, the third island pattern IP3, the fourth bridge pattern BP4, the fourth island pattern IP4, and the twelfth bridge pattern BP12. The fourth gap G4 of the island pattern group IPG may be connected to the fifth gap G5 of another island pattern group IPG adjacent thereto in the second direction DR2 (for example, on the upper side). The fifth gap G5 of the island pattern group IPG may be connected to the fourth gap G4 of another island pattern group IPG adjacent thereto in the second direction DR2 (for example, on the lower side).

As shown in FIG. 6, due to the gaps G1 to G5 defined by the plurality of island patterns IP and the plurality of bridge patterns BP, the display area DAA may be easily stretched in the first direction DR1 and the second direction DR2. While the display area DAA includes the plurality of island patterns IP, the plurality of bridge patterns BP, and the plurality of gaps G1 to G5, the non-display area NDA includes none of the plurality of island patterns IP, the plurality of bridge patterns BP, and the plurality of gaps G1 to G5. Therefore, when the display device 10 is stretched, the elongation of the display area DAA may be higher than that of the non-display area NDA.

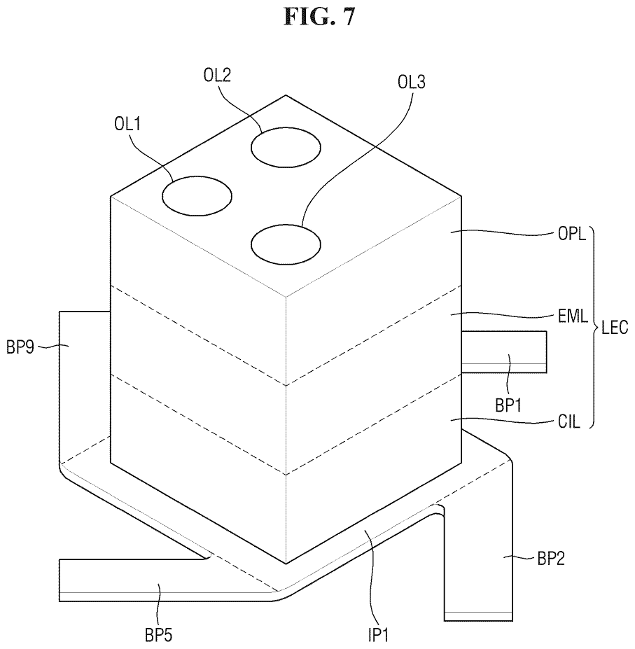

The plurality of pixel light emitting chips LEC (or a plurality of pixel light emitting modules, see, for example, FIG. 7) may be respectively disposed on the plurality of island patterns IP. The plurality of pixel light emitting chips LEC may be disposed on the plurality of island patterns IP in a one-to-one correspondence. Because the plurality of pixel light emitting chips LEC are disposed on the plurality of island patterns IP that are not stretched without being disposed on the plurality of bridge patterns BP that are stretched, the plurality of pixel light emitting chips LEC may be stably positioned on the plurality of island patterns IP even when the display device 10 is stretched.

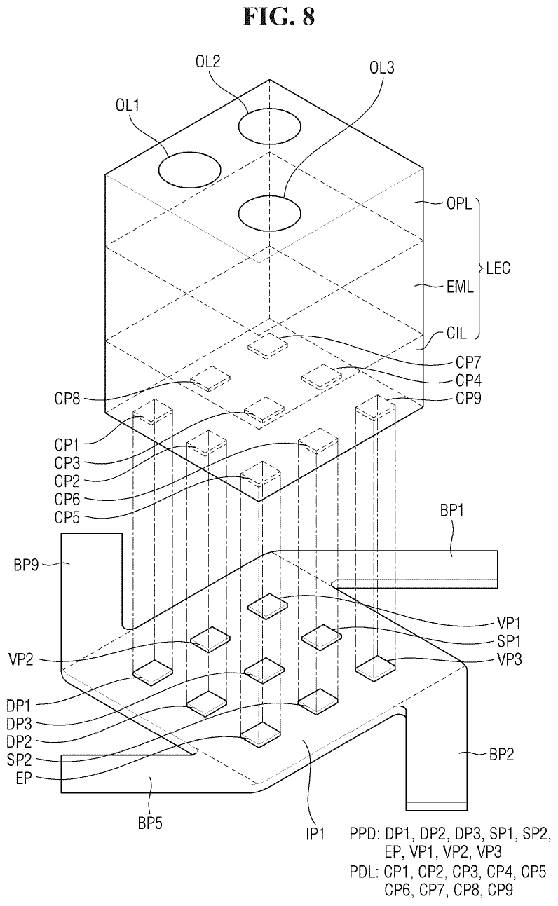

FIG. 7 is a perspective view illustrating a first island pattern and a pixel light emitting chip in an area A of FIG. 6. FIG. 8 is an exploded perspective view illustrating a first island pattern and a pixel light emitting chip in the area A of FIG. 6.

Referring to FIGS. 7 and 8, the plurality of pixel pads PPD and the pixel light emitting chip LEC are disposed on the first island pattern IP1.

The plurality of pixel pads PPD include the plurality of scan pads SP1, SP2, and EP, the plurality of data pads DP1, DP2, and DP3, and the plurality of power pads VP1, VP2, and VP3. The plurality of scan pads SP1, SP2, and EP, the plurality of data pads DP1, DP2, and DP3, and the plurality of power pads VP1, VP2, and VP3 may be referred to as first to ninth pixel pads, respectively.

Each of the plurality of pixel light emitting chips LEC includes a pad layer PDL including a plurality of chip pads CP1 to CP9, a pixel circuit layer CIL in which a plurality of transistors are disposed, a light emitting element layer EML in which a plurality of light emitting elements are disposed, and an optical layer OPL including a plurality of light exit areas OL1, OL2, and OL3.

The plurality of chip pads CP1 to CP9 may be electrically connected to the plurality of pixel pads PPD by using a conductive adhesive member such as an anisotropic conductive film. Alternatively, the plurality of chip pads CP1 to CP9 may be electrically connected to the plurality of pixel pads PPD by soldering or melting bonding.

Each of the plurality of pixel light emitting chips LEC may include the unit pixel PXG. The unit pixel PXG may include the first pixel PX1 emitting first light through the first light exit area OL1, the second pixel PX2 emitting second light through the second light exit area OL2, and the third pixel PX3 emitting third light through the third light exit area OL3. In this case, the pixel circuit layer CIL of each of the plurality of pixel light emitting chips LEC may include three pixel circuit units PDU, the light emitting element layer EML of each of the plurality of pixel light emitting chips LEC may include three light emitting elements LEL, and the optical layer OPL of each of the plurality of pixel light emitting chips LEC may include three light exit areas OL1, OL2, and OL3.

The first light may be light of a red wavelength band, the second light may be light of a green wavelength band, and the third light may be light of a blue wavelength band. The red wavelength band may be a wavelength band of light having a main peak wavelength in the range of approximately 600 nm to 750 nm, the green wavelength band may be a wavelength band of light having a main peak wavelength in the range of approximately 480 nm to 560 nm, and the blue wavelength band may be a wavelength band of light having a main peak wavelength in the range of approximately 370 nm to 460 nm. However, the present disclosure is not limited thereto.

The plurality of chip pads CP1 to CP9 may be respectively disposed on the plurality of pixel pads PPD. The plurality of chip pads CP1 to CP9 may be disposed on the plurality of pixel pads PPD in a one-to-one correspondence. The plurality of chip pads CP1 to CP9 may overlap the plurality of pixel pads PPD in the third direction DR3.

The plurality of chip pads CP1 to CP9 may include first to ninth chip pads CP1 to CP9. When each of the plurality of pixel light emitting chips LEC includes the three pixels PX1, PX2, and PX3, the first chip pad CP1 may be disposed on the first data pad DP1 corresponding to a pad of the first pixel PX1. The first chip pad CP1 may be disposed to correspond to the first data pad DP1. The first chip pad CP1 may overlap the first data pad DP1 in the third direction DR3.

The second chip pad CP2 may be disposed on the second data pad DP2 corresponding to a pad of the second pixel PX2. The second chip pad CP2 may be disposed to correspond to the second data pad DP2. The second chip pad CP2 may overlap the second data pad DP2 in the third direction DR3.

The third chip pad CP3 may be disposed on the third data pad DP3 corresponding to a pad of the third pixel PX3. The third chip pad CP3 may be disposed to correspond to the third data pad DP3. The third chip pad CP3 may overlap the third data pad DP3 in the third direction DR3.

The fourth chip pad CP4 may be disposed on the first scan pad SP1 corresponding to the fourth pixel pad. The fourth chip pad CP4 may be disposed to correspond to the first scan pad SP1. The fourth chip pad CP4 may overlap the first scan pad SP1 in the third direction DR3.

The fifth chip pad CP5 may be disposed on an emission pad EP corresponding to the fifth pixel pad. The fifth chip pad CP5 may be disposed to correspond to the emission pad EP. The fifth chip pad CP5 may overlap the emission pad EP in the third direction DR3 (e.g., the thickness direction of the pixel light emitting chips LEC).

The sixth chip pad CP6 may be disposed on the second scan pad SP2 corresponding to the sixth pixel pad. The sixth chip pad CP6 may be disposed to correspond to the second scan pad SP2. The sixth chip pad CP6 may overlap the second scan pad SP2 in the third direction DR3.

The seventh chip pad CP7 may be disposed on the second power pad VP2 corresponding to the seventh pixel pad. The seventh chip pad CP7 may be disposed to correspond to the second power pad VP2. The seventh chip pad CP7 may overlap the second power pad VP2 in the third direction DR3.

The eighth chip pad CP8 may be disposed on the first power pad VP1 corresponding to the eighth pixel pad. The eighth chip pad CP8 may be disposed to correspond to the first power pad VP1. The eighth chip pad CP8 may overlap the first power pad VP1 in the third direction DR3.

The ninth chip pad CP9 may be disposed on the third power pad VP3 corresponding to the ninth pixel pad. The ninth chip pad CP9 may be disposed to correspond to the third power pad VP3. The ninth chip pad CP9 may overlap the third power pad VP3 in the third direction DR3.

The pixel circuit layer CIL includes the plurality of pixel circuit units PDU. As shown in FIG. 4, each of the plurality of pixel circuit units PDU includes the driving transistor DT, at least one switch element, and the capacitor C1. The at least one switch element may include the first to sixth transistors ST1, ST2, ST3, ST4, ST5, and ST6, but the present disclosure is not limited thereto.

For example, the plurality of pixel circuit units PDU may include the pixel circuit unit PDU of the first pixel PX1, the pixel circuit unit PDU of the second pixel PX2, and the pixel circuit unit PDU of the third pixel PX3. The pixel circuit unit PDU of the first pixel PX1, the pixel circuit unit PDU of the second pixel PX2, and the pixel circuit unit PDU of the third pixel PX3 are connected to different data lines. Specifically, the pixel circuit unit PDU of the first pixel PX1 may be connected to the first chip pad CP1 to receive a data voltage of a first data line RDL, the pixel circuit unit PDU of the second pixel PX2 may be connected to the second chip pad CP2 to receive a data voltage of a second data line GDL, and the pixel circuit unit PDU of the third pixel PX3 may be connected to the third chip pad CP3 to receive a data voltage of a third data line BDL.

The light emitting element layer EML includes the plurality of light emitting elements LEL. For example, the plurality of light emitting elements LEL may include the light emitting element LEL of the first pixel PX1, the light emitting element LEL of the second pixel PX2, and the light emitting element LEL of the third pixel PX3. In this case, the light emitting element LEL of the first pixel PX1 may emit light in response to the driving current of the pixel circuit unit PDU of the first pixel PX1. The light emitting element LEL of the second pixel PX2 may emit light in response to the driving current of the pixel circuit unit PDU of the second pixel PX2. The light emitting element LEL of the third pixel PX3 may emit light in response to the driving current of the pixel circuit unit PDU of the third pixel PX3.

The optical layer OPL includes the plurality of light exit areas OL1 to OL3. The plurality of light exit areas OL1 to OL3 include the first light exit area OL1 through which the light of the light emitting element LEL of the first pixel PX1 is emitted, the second light exit area OL2 through which the light of the light emitting element LEL of the second pixel PX2 is emitted, and the third light exit area OL3 through which the light of the light emitting element LEL of the third pixel PX3 is emitted.

As illustrated in FIGS. 7 and 8, each of the plurality of pixel light emitting chips LEC includes the pad layer PDL including the plurality of chip pads CP1 to CP9 connected to the plurality of pixel pads PPD respectively disposed on the plurality of island patterns IP, the pixel circuit layer CIL in which the pixel circuit units PDU of the first to third pixels PX1 to PX3 are disposed, the light emitting element layer EML in which the light emitting elements LEL of the first to third pixels PX1 to PX3 are disposed, and the optical layer OPL including the first to third light exit areas OL1, OL2, and OL3 of the first to third pixels PX1 to PX3. That is, the pixel light emitting chip LEC may be a chip in which the pixel circuit layer CIL, the light emitting element layer EML, and the optical layer OPL are integrated. Therefore, even if the area of the island pattern IP corresponding to the non-stretching portion is reduced in order to implement a high-resolution display device, the plurality of pixel light emitting chips LEC only need to be attached on the plurality of island patterns IP, respectively. Thus, it is possible to provide a stretchable display device with a high degree of pixel integration.

For simplicity of description, although FIGS. 7 and 8 illustrate that the area of the pixel light emitting chip LEC is smaller than the area of the first island pattern IP1, the present disclosure is not limited thereto. For example, the area of the pixel light emitting chip LEC may be larger than the area of the first island pattern IP1.

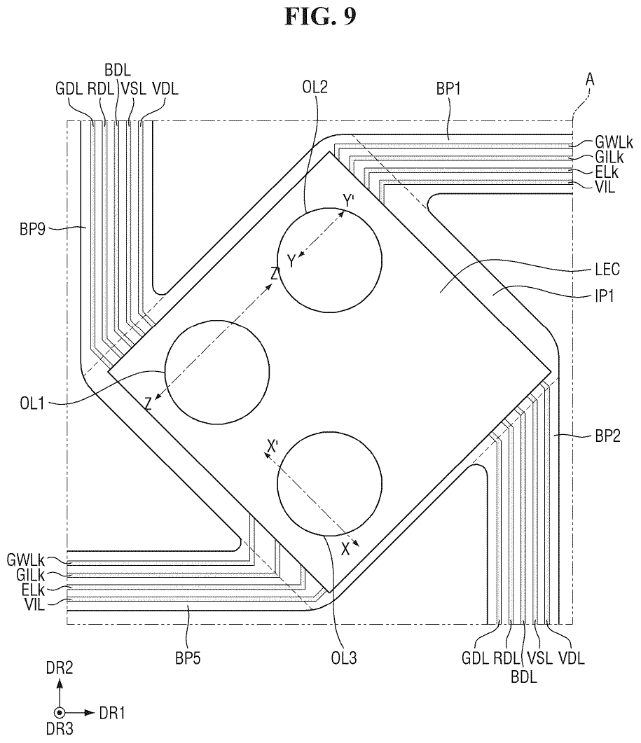

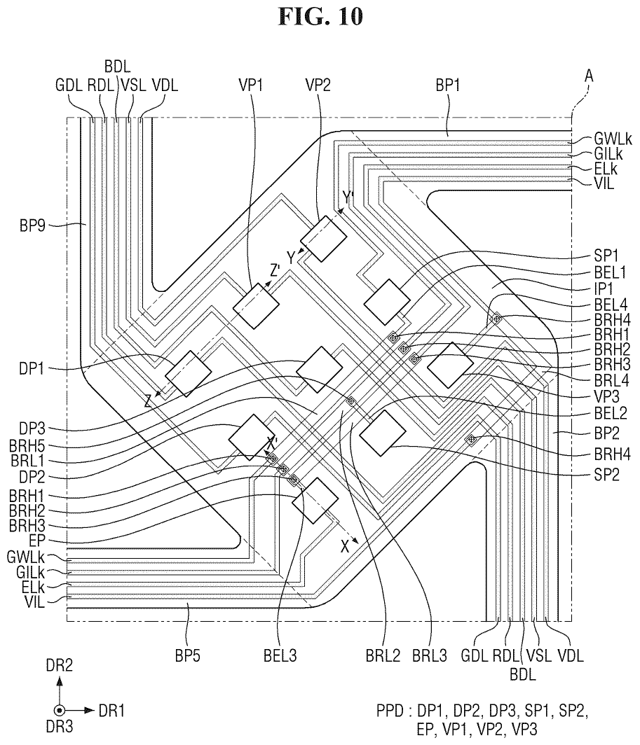

FIG. 9 is a layout diagram illustrating one example of a plurality of scan lines, a plurality of data lines, a plurality of power lines, a plurality of bridges, and a plurality of pixel pads in the area A of FIG. 6. FIG. 10 is a layout diagram illustrating a first island pattern and first to third light exit areas of a pixel light emitting chip in the area A of FIG. 6.

Referring to FIGS. 9 and 10, the first data line RDL, the second data line GDL, the third data line BDL, the first power line VSL, and the second power line VDL extend in the second direction DR2, so that they may be arranged in the ninth bridge pattern BP9, the first island pattern IP1, and the second bridge pattern BP2. The first data line RDL may be a line for supplying a data voltage to the first pixel PX1 of the pixel light emitting chip LEC. The second data line GDL may be a line for supplying a data voltage to the second pixel PX2 of the pixel light emitting chip LEC. The third data line BDL may be a line for supplying a data voltage to the third pixel PX3 of the pixel light emitting chip LEC. The first power line VSL may be a line for supplying the first power voltage VSS, and the second power line VDL may be a line for supplying the second power voltage VDD.

Because the k^{th} write scan line GWLk, the k^{th} initialization scan line GILk, the k^{th} emission line ELk, and the third power line VIL extend in the first direction DR1, they may be arranged in the fifth bridge pattern BP5, the first island pattern IP1, and the first bridge pattern BP1. The k^{th} write scan line GWLk may be a line for supplying a write scan signal to the first to third pixels PX1, PX2, and PX3 of the pixel light emitting chip LEC. The k^{th} initialization scan line GILk may be a line for supplying a initialization scan signal to the first to third pixels PX1, PX2, and PX3 of the pixel light emitting chip LEC. The third power line VIL may be a line for supplying the third power voltage VINT.

The first data line RDL extending from the ninth bridge pattern BP9 and the first data line RDL extending from the second bridge pattern BP2 may be directly connected to the first data pad DP1. The second data line GDL extending from the ninth bridge pattern BP9 and the second data line GDL extending from the second bridge pattern BP2 may be directly connected to the second data pad DP2. The third data line BDL extending from the ninth bridge pattern BP9 and the third data line BDL extending from the second bridge pattern BP2 may be directly connected to the third data pad DP3. The first power line VSL extending from the ninth bridge pattern BP9 and the first power line VSL extending from the second bridge pattern BP2 may be directly connected to the first power pad VP1. The second power line VDL extending from the ninth bridge pattern BP9 and the second power line VDL extending from the second bridge pattern BP2 may be directly connected to the second power pad VP2.

In the first island pattern IP1, a first bridge line BRL1, a second bridge line BRL2, a third bridge line BRL3, a fourth bridge line BRL4, a first bridge connection line BEL1, a second bridge connection line BEL2, a third bridge connection line BEL3, and a fourth bridge connection line BEL4 may be arranged.

One end of the first bridge line BRL1 may be connected to the k^{th} write scan line GWLk extending from the fifth bridge pattern BP5 through a first bridge contact hole BRH1. The other end of the first bridge line BRL1 may be connected to the first bridge connection line BEL1, which is connected to the first scan pad SP1, through the first bridge contact hole BRH1. The k^{th} write scan line GWLk extending from the first bridge pattern BP1 may be directly connected to the first scan pad SP1.

One end and the other end of the second bridge line BRL2 may be connected to the k^{th} initialization scan line GILk through a second bridge contact hole BRH2. The middle of the second bridge line BRL2 may be connected to the second bridge connection line BEL2, which is connected to the second scan pad SP2, through a fifth bridge contact hole BRH5.

One end of the third bridge line BRL3 may be connected to the third bridge connection line BEL3 through a third bridge contact hole BRH3. The other end thereof may be connected to the k^{th} emission line ELk extending from the first bridge pattern BP1 through the third bridge contact hole BRH3. The k^{th} emission line ELk extending from the fifth bridge pattern BP5 may be directly connected to the emission pad EP.

One end of the fourth bridge line BRL4 may be connected to the third power line VIL extending from the fifth bridge pattern BP5 through a fourth bridge contact hole BRH4. The other end of the fourth bridge line BRL4 may be connected to the third power line VIL extending from the first bridge pattern BP1 through the fourth bridge contact hole BRH4. The fourth bridge connection line BEL4 directly connected to the third power pad VP3 may be directly connected to the third power line VIL extending from the first bridge pattern BP1.

The first data line RDL, the second data line GDL, the third data line BDL, the first power line VSL, the second power line VDL, the k^{th} write scan line GWLk, the k^{th} initialization scan line GILk, the k^{th} emission line ELk, the third power line VIL, the first bridge connection line BEL1, the second bridge connection line BEL2, the third bridge connection line BEL3, and the fourth bridge connection line BEL4 may be formed of a first metal layer. The first bridge line BRL1, the second bridge line BRL2, the third bridge line BRL3, and the fourth bridge line BRL4 may be formed of a second metal layer. Thus, the first bridge line BRL1, the second bridge line BRL2, the third bridge line BRL3, and the fourth bridge line BRL4 may cross the first data line RDL, the second data line GDL, the third data line BDL, the first power line VSL, and the second power line VDL.

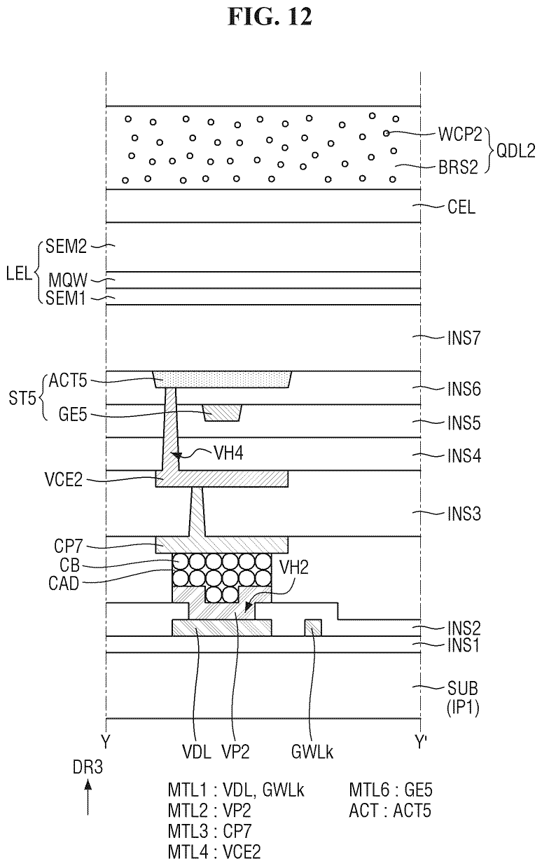

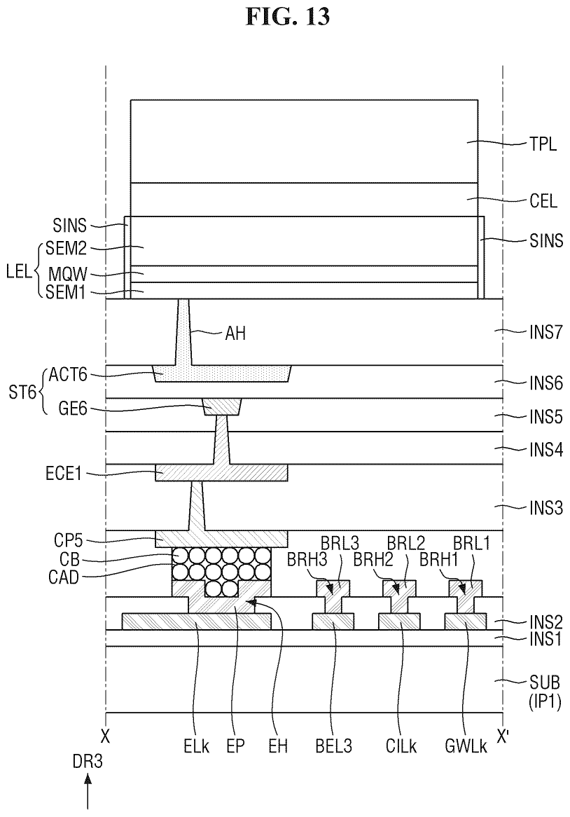

FIG. 11 is a cross-sectional view showing an example of a first island pattern and a pixel light emitting chip taken along the line Z-Z′ of FIGS. 9 and 10. FIG. 12 is a cross-sectional view showing an example of a first island pattern and a pixel light emitting chip taken along the line Y-Y′ of FIGS. 9 and 10. FIG. 13 is a cross-sectional view showing an example of a first island pattern and a pixel light emitting chip taken along the line X-X′ of FIGS. 9 and 10.

Referring to FIGS. 11 to 13, the substrate SUB may be made of an insulating material such as polymer resin. For example, the substrate SUB may be formed of polyimide. The substrate SUB may be a flexible substrate which can be bent, folded, and/or rolled.

A first insulating layer INS1 may be disposed on the substrate SUB. The first insulating layer INS1 may be formed of an inorganic layer such as silicon nitride, silicon oxynitride, silicon oxide, titanium oxide, and/or aluminum oxide.

A first metal layer MTL1 may be disposed on the first insulating layer INS1. The first metal layer MTL1 includes the first data line RDL, the second data line GDL, the third data line BDL, the first power line VSL, the second power line VDL, the k^{th} write scan line GWLk, the k^{th} initialization scan line GILk, the k^{th} emission line ELk, the third power line VIL, the first bridge connection line BEL1, the second bridge connection line BEL2, the third bridge connection line BEL3, and the fourth bridge connection line BEL4. The first metal layer may be formed as a single layer or multiple layers made of at least one of molybdenum (Mo), aluminum (Al), chromium (Cr), gold (Au), titanium (Ti), nickel (Ni), neodymium (Nd), and/or copper (Cu), and/or an alloy thereof.

A second insulating layer INS2 may be disposed on the first metal layer MTL1. The second insulating layer INS2 may be formed of an inorganic layer such as silicon nitride, silicon oxynitride, silicon oxide, titanium oxide, and/or aluminum oxide.

A second metal layer MTL2 may be disposed on the second insulating layer INS2. The second metal layer MTL2 includes the plurality of scan pads SP1, SP2, and EP, the plurality of data pads DP1, DP2, and DP3, the plurality of power pads VP1, VP2, and VP3, the first bridge line BRL1, the second bridge line BRL2, the third bridge line BRL3, and the fourth bridge line BRL4. The second metal layer MTL2 may be formed as a single layer or multiple layers made of at least one of molybdenum (Mo), aluminum (Al), chromium (Cr), gold (Au), titanium (Ti), nickel (Ni), neodymium (Nd), and/or copper (Cu), and/or an alloy thereof.

The first data pad DP1 may be connected to the first data line RDL through a first data contact hole DH1 penetrating the second insulating layer INS2. The first power pad VP1 may be connected to the first power line VSL through a first power contact hole VH1 penetrating the second insulating layer INS2. The emission pad EP may be connected to the k^{th} emission line ELk through an emission contact hole EH penetrating the second insulating layer INS2. The second power pad VP2 may be connected to the second power line VDL through a second power contact hole VH2 penetrating the second insulating layer INS2.

The first bridge line BRL1 may be connected to the k^{th} write scan line GWLk through the first bridge contact hole BRH1 penetrating the second insulating layer INS2, and may be connected to the first bridge connection line BEL1, which is connected to the first scan pad SP1, through another first bridge contact hole BRH1 penetrating the second insulating layer INS2.

The second bridge line BRL2 may be connected to the k^{th} initialization scan line GILk through the second bridge contact hole BRH2 penetrating the second insulating layer INS2, and may be connected to the second bridge connection line BEL2 through the fifth bridge contact hole BRH5 penetrating the second insulating layer INS2.

The third bridge line BRL3 may be connected to the third bridge connection line BEL3 through the third bridge contact hole BRH3 penetrating the second insulating layer INS2, and may be connected to the k^{th} emission line ELk through another third bridge contact hole BRH3 penetrating the second insulating layer INS2.

The fourth bridge line BRL4 may be connected to the third power line VIL through the fourth bridge contact hole BRH4 penetrating the second insulating layer INS2, and may be connected to the third power line VIL through another fourth bridge contact hole BRH4 penetrating the second insulating layer INS2.

A conductive adhesive member CAD may be disposed on the plurality of scan pads SP1, SP2, and EP, the plurality of data pads DP1, DP2, and DP3, and the plurality of power pads VP1, VP2, and VP3. For example, the conductive adhesive member CAD may be an anisotropic conductive film including a plurality of conductive balls CB as shown in FIGS. 11 to 13, but the present disclosure is not limited thereto.

The pad layer PDL including the plurality of chip pads CP1 to CP9 may be disposed on the conductive adhesive member CAD. The plurality of chip pads CP1 to CP9 may be formed as a single layer or multiple layers made of at least one of molybdenum (Mo), aluminum (Al), chromium (Cr), gold (Au), titanium (Ti), nickel (Ni), neodymium (Nd), and/or copper (Cu), and/or an alloy thereof.

A third insulating layer INS3 may be disposed on the pad layer PDL including the plurality of chip pads CP1 to CP9. The third insulating layer INS3 may be formed of an inorganic layer such as silicon nitride, silicon oxynitride, silicon oxide, titanium oxide, and/or aluminum oxide. Alternatively, the third insulating layer INS3 may be an organic layer such as acryl resin, epoxy resin, phenolic resin, polyamide resin, polyimide resin and/or the like.

A third metal layer MTL3 may be disposed on the third insulating layer INS3. The third metal layer MTL3 may be connected to a plurality of connection electrodes DCE1, VCE1, VCE2, and ECE1. The plurality of connection electrodes DCE1, VCE1, VCE2, and ECE1 include a first data connection electrode DCE1, a first power connection electrode VCE1, a second power connection electrode VCE2, and a first emission connection electrode ECE1. The third metal layer MTL3 may be formed as a single layer or multiple layers made of at least one of molybdenum (Mo), aluminum (A1), chromium (Cr), gold (Au), titanium (Ti), nickel (Ni), neodymium (Nd), and/or copper (Cu), and/or an alloy thereof.

A fourth insulating layer INS4 may be disposed on the third metal layer MTL3. The fourth insulating layer INS4 may be formed of an inorganic layer such as silicon nitride, silicon oxynitride, silicon oxide, titanium oxide, and/or aluminum oxide.

A fourth metal layer MTL4 may be disposed on the fourth insulating layer INS4. The fourth metal layer MTL4 may include the third power connection electrode VCE3 and one electrode of the capacitor C1. The fourth metal layer MTL4 may be formed as a single layer or multiple layers made of at least one of molybdenum (Mo), aluminum (Al), chromium (Cr), gold (Au), titanium (Ti), nickel (Ni), neodymium (Nd), and/or copper (Cu), and/or an alloy thereof.

A fifth insulating layer INS5 may be disposed on the fourth metal layer MTL4. The fifth insulating layer INS5 may be formed of an inorganic layer such as silicon nitride, silicon oxynitride, silicon oxide, titanium oxide, and/or aluminum oxide.

A fifth metal layer MTL5 may be disposed on the fifth insulating layer INS5. The fifth metal layer MTL5 may include a gate electrode of the driving transistor DT, a gate electrode GE2 of the second transistor ST2, a gate electrode GE6 of the sixth transistor ST6, and a fourth power connection electrode VCE4. Further, the fifth metal layer MTL5 may include a gate electrode of the first transistor ST1, a gate electrode of the third transistor ST3, a gate electrode of the fourth transistor ST4, a gate electrode GE5 of the fifth transistor ST5, and the other electrode of the capacitor C1. The fifth metal layer MTL5 may be formed as a single layer or multiple layers made of at least one of molybdenum (Mo), aluminum (Al), chromium (Cr), gold (Au), titanium (Ti), nickel (Ni), neodymium (Nd), and/or copper (Cu), and/or an alloy thereof.

A sixth insulating layer INS6 may be disposed on the fifth metal layer MTL5. The sixth insulating layer INS6 may be formed of an inorganic layer such as silicon nitride, silicon oxynitride, silicon oxide, titanium oxide, and/or aluminum oxide.

An active layer ACT may be disposed on the sixth insulating layer INS6. The active layer ACT may include an active pattern of the driving transistor DT, an active pattern ACT2 of the second transistor ST2, and an active pattern ACT6 of the sixth transistor ST6. Further, the active layer ACT may include an active pattern of the first transistor ST1, an active pattern of the third transistor ST3, an active pattern of the fourth transistor ST4, and an active pattern ACT5 of the fifth transistor ST5. The active layer ACT may be formed of polysilicon and/or an oxide semiconductor.

The active pattern of the driving transistor DT may include a channel region overlapping the gate electrode in the third direction DR3, a source region disposed on one side of the channel region, and a drain region disposed on the other side of the channel region. The active pattern ACT2 of the second transistor ST2 may include a channel region overlapping the gate electrode GE2 in the third direction DR3, a source region disposed on one side of the channel region, and a drain region disposed on the other side of the channel region. The active pattern ACT6 of the sixth transistor ST6 may include a channel region overlapping the gate electrode GE6 in the third direction DR3, a source region disposed on one side of the channel region, and a drain region disposed on the other side of the channel region. The active pattern ACT6 of the sixth transistor ST6 may be connected to a first semiconductor layer SEM1 of the light emitting element LEL through an active contact hole AH penetrating a seventh insulating layer INS7.

The seventh insulating layer INS7 may be disposed on the active layer ACT. The seventh insulating layer INS7 may be an organic layer such as acryl resin, epoxy resin, phenolic resin, polyamide resin, polyimide resin, and/or the like.

The light emitting elements LEL may be disposed on the seventh insulating layer INS7.

The first data connection electrode DCE1 may be connected to the source region of the active pattern ACT2 of the second transistor ST2 through a second data contact hole DH2 penetrating the fourth insulating layer INS4, the fifth insulating layer INS5, and the sixth insulating layer INS6. Each of the chip pads CP1 to CP9 may be electrically connected to the active pattern of the corresponding transistor.

A first emission connection electrode ECE1 may be connected to the gate electrode GE6 of the sixth transistor ST6 through a second scan contact hole EH2 penetrating the fourth insulating layer INS4 and the fifth insulating layer INS5. The fifth chip pad CP5 may be connected to the first emission connection electrode ECE1 through a first scan contact hole EH1 penetrating the third insulating layer INS3.

The first power connection electrode VCE1 may be connected to the eighth chip pad CP8 through a contact hole penetrating the third insulating layer INS3. The first power connection electrode VCE1 may be connected to the third power connection electrode VCE3 through a third power contact hole VH3 penetrating the fourth insulating layer INS4. The third power connection electrode VCE3 may be connected to the fourth power connection electrode VCE4 through a fifth power contact hole VH5 penetrating the fifth insulating layer INS5. The fourth power connection electrode VCE4 may be connected to a common electrode layer CEL through a sixth power contact hole VH6 penetrating the sixth insulating layer INS6 and the seventh insulating layer INS7.

The second power connection electrode VCE2 may be connected to the seventh chip pad CP7 through a contact hole penetrating the third insulating layer INS3. The second power connection electrode VCE2 may be connected to a source region of an active pattern ACT5 of the fifth transistor ST5 through a fourth power contact hole VH4 penetrating the fourth insulating layer INS4, the fifth insulating layer INS5, and the sixth insulating layer INS6.

Each of the light emitting elements LEL includes the first semiconductor layer SEM1, an active layer MQW, and a second semiconductor layer SEM2. In one or more embodiments, the light emitting elements LEL may include a superlattice layer.

The first semiconductor layer SEM1 may be disposed on the seventh insulating layer INS7. The first semiconductor layer SEM1 may be formed of GaN doped with a first conductivity type dopant such as Mg, Zn, Ca, Sr, and/or Ba.

An electron blocking layer may be additionally disposed on the first semiconductor layer SEM1. The electron blocking layer may be a layer for suppressing or preventing too many electrons from flowing into the active layer MQW. The electron blocking layer may be AlGaN and/or p-AlGaN doped with p-type Mg.

The active layer MQW may be disposed on the first semiconductor layer SEM1. The active layer MQW may emit light by recombining of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately laminated. At this time, the well layer may be formed of InGaN, and the barrier layer may be formed of GaN and/or AlGaN, but the present disclosure is not limited thereto. Alternatively, the active layer MQW may have a structure in which semiconductor materials having large band gap energy and semiconductor materials having small band gap energy are alternately stacked, and may include other Group III to Group V semiconductor materials according to the wavelength band of the emitted light.

When the active layer MQW includes InGaN, the color of emitted light may vary depending on the content of indium (In). For example, as the content of indium (In) increases, the wavelength band of the light emitted by the active layer may shift to the red wavelength band, and as the content of indium (In) decreases, the wavelength band of the light emitted by the active layer may shift to the blue wavelength band. For example, the active layer MQW of the light emitting element LEL that emits light in the blue wavelength band may contain about 10 wt % to 20 wt % of indium.

In one or more embodiments, the superlattice layer may be additionally disposed on the active layer MQW. The superlattice layer may be a layer for relieving stress between the second semiconductor layer SEM2 and the active layer MQW. The superlattice layer may be formed of InGaN and/or GaN.

The second semiconductor layer SEM2 may be disposed on the active layer MQW. The second semiconductor layer SEM2 may be doped with a second conductive dopant such as Si, Ge, Sn, and/or the like. For example, the second semiconductor layer SEM2 may be n-GaN doped with n-type Si.

The common electrode layer CEL may be commonly connected to the second semiconductor layers SEM2 of the plurality of light emitting elements LEL. The common electrode layer CEL may receive the first power voltage VSS through the first power line VSL, the first power pad VP1, the first power connection electrode VCE1, the third power connection electrode VCE3, the fourth power connection electrode VCE4, and a common connection electrode. The common electrode layer CEL may be formed of a transparent conductive oxide (TCO) such as indium tin oxide (ITO) and/or indium zinc oxide (IZO). Alternatively, the common electrode layer CEL may be formed of a transparent conductive material (TCO), or a semi-transmissive conductive material such as magnesium (Mg), silver (Ag), and/or an alloy of magnesium (Mg) and/or silver (Ag).

The common electrode layer CEL may be disposed on a side insulating layer SINS disposed on the side of the light emitting element LEL. The side insulating layer SINS may be a layer for insulating the common electrode layer CEL from a side surface of the light emitting element layer EML. The side insulating layer SINS may be formed of an inorganic layer such as silicon nitride, silicon oxynitride, silicon oxide, titanium oxide, and/or aluminum oxide.

The optical layer OPL includes a first light conversion layer QDL1, a second light conversion layer QDL2, and a light transmitting layer TPL.

The first light conversion layer QDL1 may be disposed in the first light exit area OL1 of the first pixel PX1. The first light conversion layer QDL1 may convert a part of light in the blue wavelength band incident from the light emitting element LEL into light in the red wavelength band. The first light conversion layer QDL1 may include a first base resin BRS1 and a first wavelength conversion particle WCP1. The first base resin BRS1 may include a light-transmissive organic material. For example, the first base resin BRS1 may contain epoxy resin, acrylic resin, cardo resin, and/or imide resin. The first wavelength conversion particle WCP1 may convert a part of light in the blue wavelength band incident from the light emitting element LEL into light in the red wavelength band. The first wavelength conversion particle WCP1 may be a quantum dot (QD), a quantum rod, a fluorescent material, and/or a phosphorescent material.

The second light conversion layer QDL2 may be disposed in the second light exit area OL2 of the second pixel PX2. The second light conversion layer QDL2 may convert a part of light in the blue wavelength band incident from the light emitting element LEL into light in the green wavelength band. The second light conversion layer QDL2 may include a second base resin BRS2 and second wavelength conversion particles WCP2. The second base resin BRS2 may contain a light-transmissive organic material. For example, the second base resin BRS2 may contain epoxy resin, acrylic resin, cardo resin, and/or imide resin. The second wavelength conversion particle WCP2 may convert a part of light in the blue wavelength band incident from the light emitting element LEL into light in the green wavelength band. The second wavelength conversion particle WCP2 may be a quantum dot (QD), a quantum rod, a fluorescent material, and/or a phosphorescent material.

The light transmitting layer TPL is disposed in the third light exit area OL3 of the third pixel PX3. The light transmitting layer TPL may include a light-transmissive organic material. For example, the light transmitting layer TPL may include epoxy resin, acrylic resin, cardo resin, imide resin, and/or the like. The light transmitting layer TPL may include substantially the same material(s) as the first base resin BRS1 and the second base resin BRS2.

A plurality of color filters may be disposed on the first light conversion layer QDL1, the second light conversion layer QDL2, and the light transmitting layer TPL. For example, a first color filter, which transmits light in the red wavelength band, and absorbs or blocks light in other wavelength bands, may be disposed on the first light conversion layer QDL1. A second color filter, which transmits light in the green wavelength band, and absorbs or blocks light in other wavelength bands, may be disposed on the second light conversion layer QDL2. A third color filter, that transmits light in the blue wavelength band, and absorbs or blocks light in other wavelength bands, may be disposed on the light transmitting layer TPL.

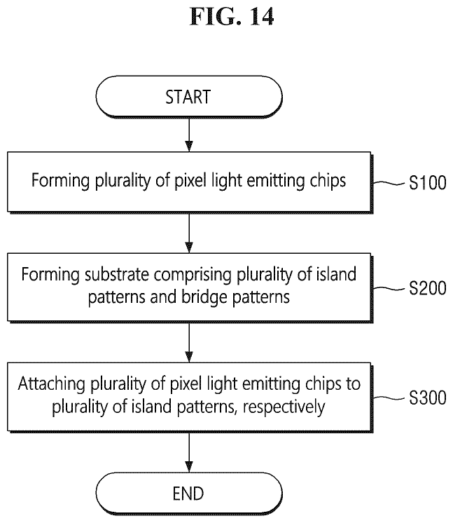

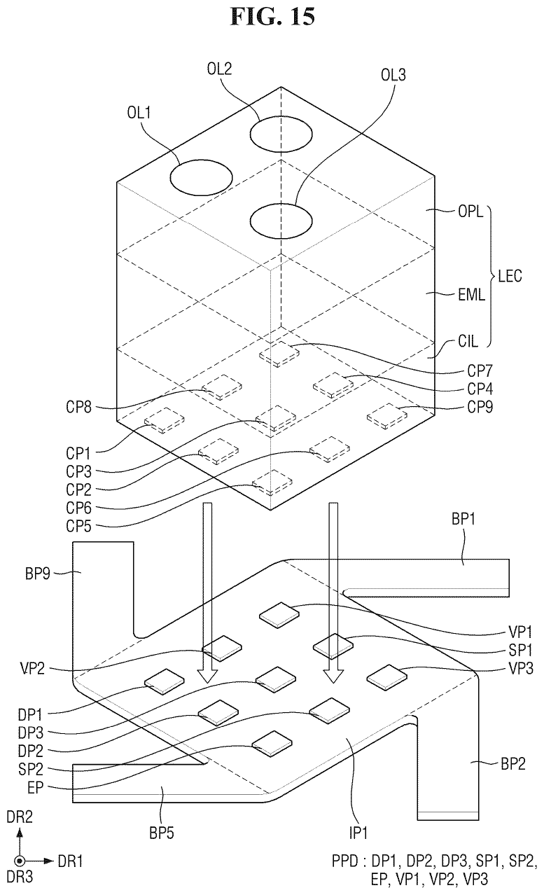

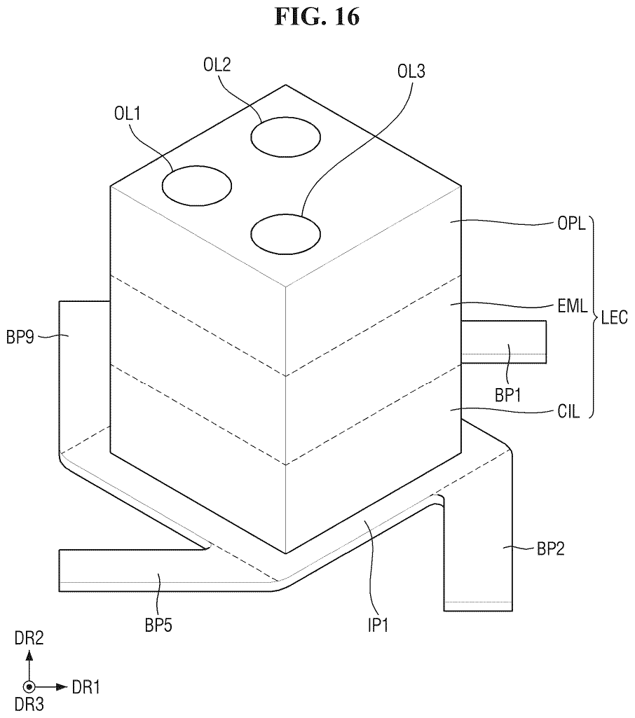

FIG. 14 is a flowchart illustrating a method for fabricating a stretchable display device according to one or more embodiments. FIGS. 15 and 16 are an exploded perspective view and a perspective view illustrating a method for fabricating a stretchable display device according to one or more embodiments, respectively.

Hereinafter, a method for fabricating a stretchable display device according to one or more embodiments will be described in detail with reference to FIGS. 14 to 16.

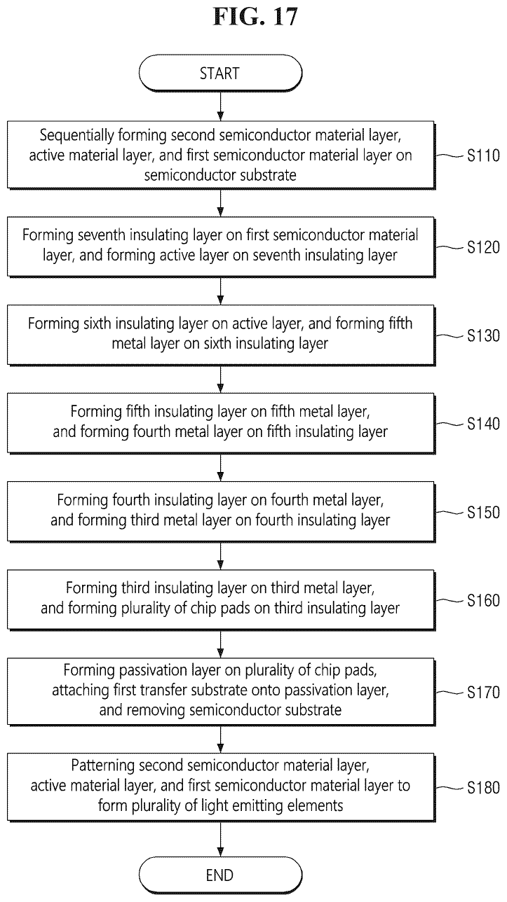

First, a plurality of pixel light emitting chips LEC are formed as shown in FIG. 15 (step S100 of FIG. 14). A method for forming the plurality of pixel light emitting chips LEC will be described in conjunction with FIGS. 17 to 26.

Secondly, in order to implement the stretchable display device 10, the substrate SUB including a plurality of island patterns IP and a plurality of bridge patterns BP is provided (step S200 of FIG. 14).

The substrate SUB including the plurality of island patterns IP and the plurality of bridge patterns BP may be provided by forming a plurality of gaps G1 to G5 by a laser process or an etching process.

Then, as shown in FIGS. 11 to 13, the first insulating layer INS1 is formed on the substrate SUB, and the first metal layer MTL1 is formed on the first insulating layer INS1. The first metal layer MTL1 includes the data lines RDL, GDL, and BDL, the k^{th} write scan lines GWLk, the k^{th} initialization scan lines GILk, the k^{th} emission lines ELk, and the power lines VSL, VDL, and VIL.

Then, as shown in FIGS. 11 to 13, the second insulating layer INS2 is formed on the first metal layer MTL1, the contact holes DH1, VH1, EH, and VH2 are formed in the second insulating layer INS2, and the second metal layer MTL2 is formed on the second insulating layer INS2. The second metal layer MTL2 includes the pixel pads PPD, the first bridge line BRL1, the second bridge line BRL2, the third bridge line BRL3, and the fourth bridge line BRL4. The pixel pads PPD include the plurality of scan pads SP1, SP2, and EP, the plurality of data pads DP1, DP2, and DP3, the plurality of power pads VP1, VP2, and VP3, the first bridge line BRL1, the second bridge line BRL2, the third bridge line BRL3, and the fourth bridge line BRL4.

Thirdly, the pixel light emitting chips LEC are attached to the island patterns IP, respectively (step S300 of FIG. 14).

The plurality of pixel light emitting chips LEC may be disposed in a one-to-one correspondence with the plurality of island patterns IP. The plurality of pixel light emitting chips LEC may be disposed on the plurality of island patterns IP that are not stretchable, and may not be disposed on the plurality of bridge patterns BP that are stretchable.

In this case, the chip pads CP1 to CP9 of the pixel light emitting chips LEC may be electrically connected to the respective pixel pads PPD of the island patterns IP by the conductive adhesive member CAD, melt-bonding, and/or soldering.

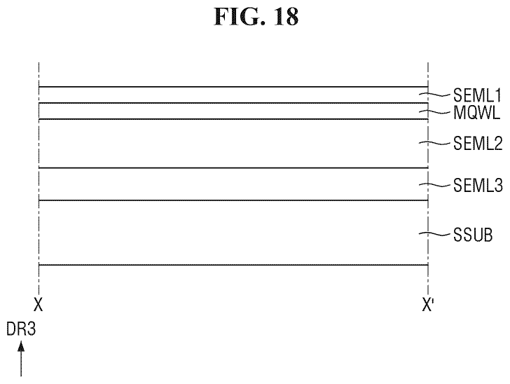

FIG. 17 is a flowchart showing an example of step S100 of FIG. 14 in detail. FIGS. 18 to 26 are cross-sectional views for describing an example of step S100 of FIG. 14. FIGS. 18 to 26 are cross-sectional views taken along the line Y-Y′ of FIG. 10.

Firstly, as shown in FIG. 18, a second semiconductor material layer SEML2, an active material layer MQWL, and a first semiconductor material layer SEML1 are sequentially formed on a semiconductor substrate SSUB (step S110 of FIG. 17).

The semiconductor substrate SSUB may be a sapphire substrate, but the present disclosure is not limited thereto. The second semiconductor material layer SEML2, the active material layer MQWL, and the first semiconductor material layer SEML1 may be disposed entirely on one surface of the semiconductor substrate SSUB. In one or more embodiments, a third semiconductor material layer SEML3 may be disposed between the semiconductor substrate SSUB and the second semiconductor material layer SEML2.

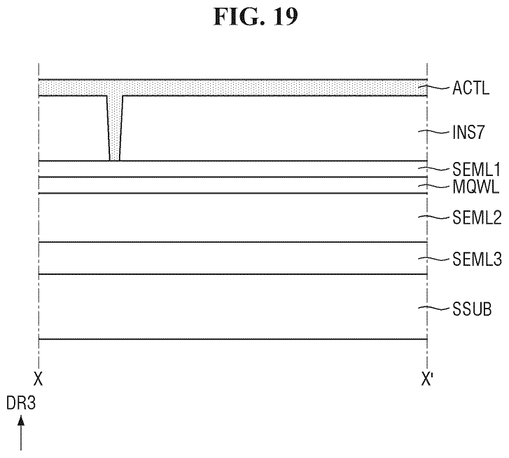

Secondly, as shown in FIGS. 19 to 21, the seventh insulating layer INS7 is formed on the first semiconductor material layer SEML1, and the active layer ACT is formed on the seventh insulating layer INS7 (step S120 of FIG. 17).

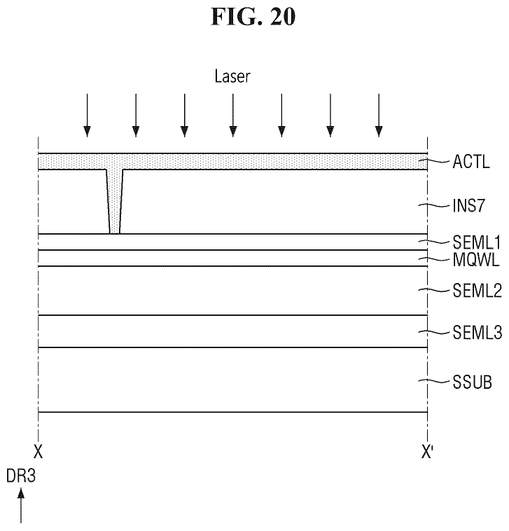

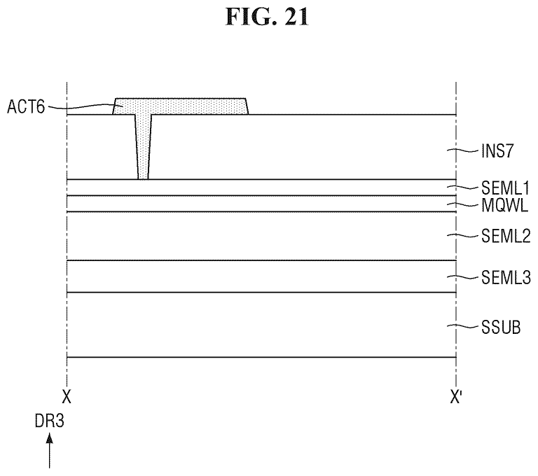

Specifically, as shown in FIG. 19, an active material layer ACTL including amorphous silicon is formed on the seventh insulating layer INS7. Then, as shown in FIG. 20, by irradiating the active material layer ACTL with a laser, the amorphous silicon is recrystallized and changed into polysilicon. Thereafter, as shown in FIG. 21, the active material layer ACTL is patterned through a photolithography process to form the active layer ACT including the active patterns ACT2, and ACT6 of the transistors DT, ST2, and ST6.

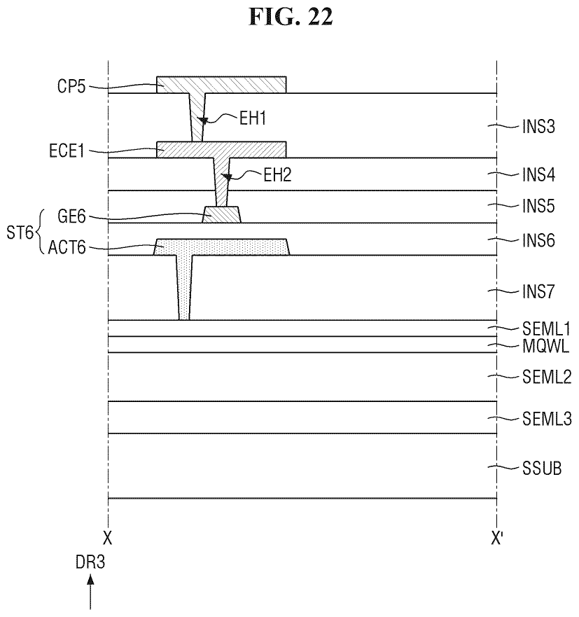

Thirdly, as shown in FIG. 22, the sixth insulating layer INS6 is formed on the active layer ACT, and the fifth metal layer MTL5 is formed on the sixth insulating layer INS6 (step S130 of FIG. 17).

The sixth insulating layer INS6 may be deposited by chemical vapor deposition. The gate electrode of the driving transistor DT of the fifth metal layer MTL5, the gate electrode GE2 of the second transistor ST2, the gate electrode GE6 of the sixth transistor ST6, the fourth power connection electrode VCE4, the gate electrode of the first transistor ST1, the gate electrode of the third transistor ST3, the gate electrode of the fourth transistor ST4, the gate electrode GE5 of the fifth transistor ST5, and the other electrode of the capacitor C1 may be patterned by a photolithography process.

Fourthly, as shown in FIG. 22, the fifth insulating layer INS5 is formed on the fifth metal layer MTL5, and the fourth metal layer MTL4 is formed on the fifth insulating layer INS5 (step S140 of FIG. 17).

The fifth insulating layer INS5 may be deposited by chemical vapor deposition. The third power connection electrode VCE3 of the fourth metal layer MTL4 and one electrode of the capacitor C1 may be patterned by a photolithography process.

Fifthly, as shown in FIG. 22, the fourth insulating layer INS4 is formed on the fourth metal layer MTL4, and the third metal layer MTL3 is formed on the fourth insulating layer INS4 (step S150 of FIG. 17).

The fourth insulating layer INS4 may be deposited by chemical vapor deposition. The plurality of connection electrodes DCE1, VCE1, VCE2, and ECE1 of the third metal layer MTL3 may be patterned by a photolithography process.

Sixthly, as shown in FIG. 22, the third insulating layer INS3 is formed on the third metal layer MTL3, and the plurality of chip pads CP1 to CP9 are formed on the third insulating layer INS3 (step S160 of FIG. 17).

The third insulating layer INS3 may be deposited by chemical vapor deposition. The plurality of chip pads CP1 to CP9 may be patterned by a photolithography process.

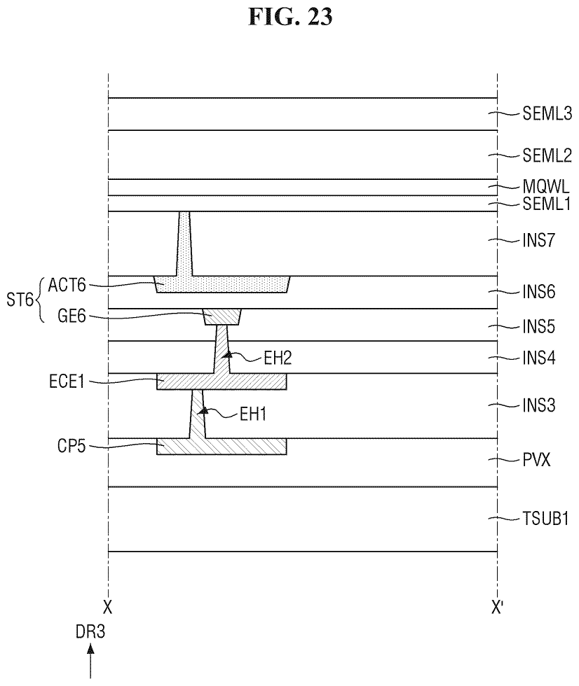

Seventhly, as shown in FIG. 23, a passivation layer PVX is formed on the plurality of chip pads CP1 to CP9, a first transfer substrate TSUB1 is attached onto the passivation layer PVX, and the semiconductor substrate SSUB is removed (step S170 of FIG. 17).

The passivation layer PVX may be an organic layer such as acrylic resin, epoxy resin, phenolic resin, polyamide resin, and/or polyimide resin.

The first transfer substrate TSUB1 may be adhered to an organic layer via a tackifier and/or the like.

The semiconductor substrate SSUB may be detached by irradiating a laser, or removed by a polishing process.

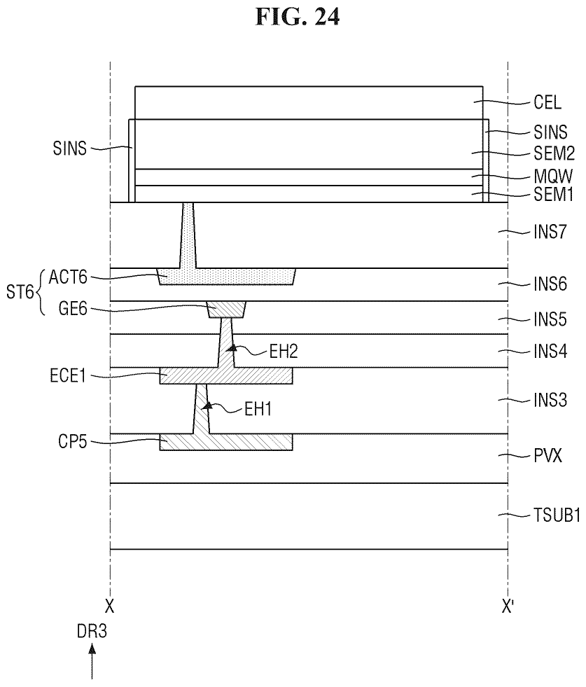

Eighthly, as shown in FIG. 24, the first semiconductor material layer SEML1, the active material layer MQWL, and the second semiconductor material layer SEML2 are patterned to form the plurality of light emitting elements LEL (step S180 of FIG. 17). In addition, although not depicted in FIG. 17, as shown in FIG. 24, a side insulating layer SINS is formed on the side surface of the light emitting elements LEL, and a common electrode layer CEL is formed on the light emitting elements LEL.

The first semiconductor material layer SEML1, the active material layer MQWL, and the second semiconductor material layer SEML2 may be patterned by a photolithography process.

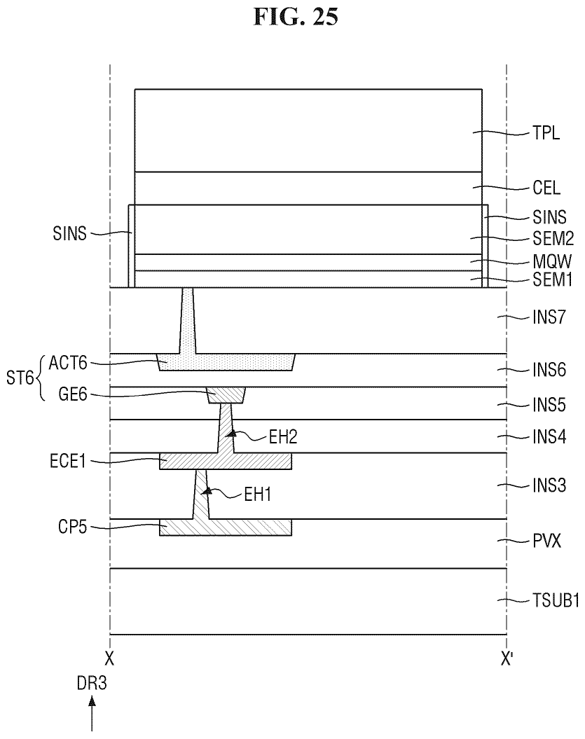

Ninthly, the optical layer OPL is formed on the plurality of light emitting elements LEL, as shown in FIG. 25.

Specifically, the first light conversion layer QDL1 is formed on the light emitting element LEL of the first pixel PX1. Then, the second light conversion layer QDL2 is formed on the light emitting element LEL of the second pixel PX2. Thereafter, the light transmitting layer TPL is formed on the light emitting element LEL of the third pixel PX3.

Alternatively, the first base resin BRS1, the second base resin BRS2, and the light transmitting layer TPL may be concurrently (e.g., simultaneously) formed on the respective light emitting elements LEL of the first pixel PX1, the second pixel PX2, and the third pixel PX3 with the same material. Then, the first wavelength conversion particle WCP1 may be injected into the first base resin BRS1, and then the second wavelength conversion particle WCP2 may be injected into the second base resin BRS2.

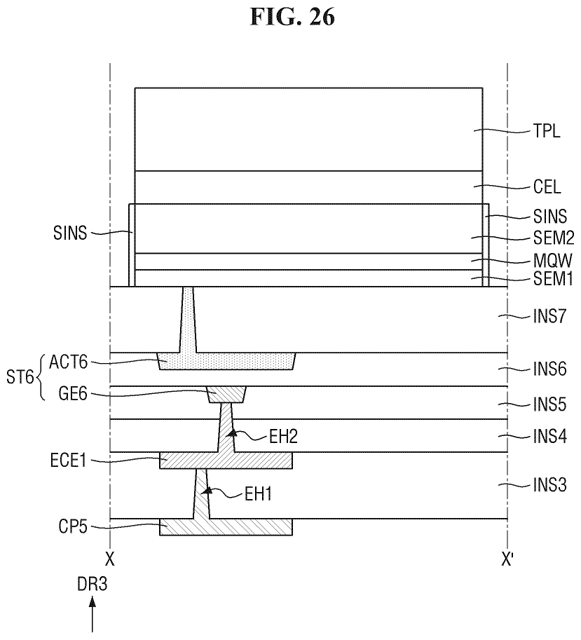

Tenthly, as shown in FIG. 26, a second transfer substrate is attached onto the optical layer OPL, and the passivation layer PVX and the first transfer substrate TSUB1 are removed to expose the plurality of chip pads CP1 to CP9.

The second transfer substrate may be adhered to the optical layer OPL via a tackifier or the like. In this case, the adhesive force between the second transfer substrate and the optical layer OPL may be higher than the adhesive force between the first transfer substrate TSUB1 and the passivation layer PVX. Therefore, even if the first transfer substrate TSUB1 is detached, the adhesion between the second transfer substrate and the optical layer OPL may be maintained.

The passivation layer PVX may be removed by an ashing process or an etching process.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate comprising a plurality of island patterns and a first bridge pattern connecting a first island pattern and a second island pattern adjacent to each other from among the plurality of island patterns; and
a plurality of pixel light emitting chips, each of the plurality of pixel light emitting chips located on a corresponding island pattern from among the plurality of island patterns,
wherein each of the plurality of pixel light emitting chips comprises:
a transistor layer comprising a plurality of transistors; and
a light emitting element layer on the transistor layer, and comprising a plurality of light emitting elements.

2. The display device of claim 1, wherein the plurality of pixel light emitting chips correspond one-to-one to the plurality of island patterns.

3. The display device of claim 1, wherein the plurality of light emitting elements comprises a light emitting element of a first pixel, a light emitting element of a second pixel, and a light emitting element of a third pixel, and
wherein each of the plurality of pixel light emitting chips further comprises a first light conversion layer on the light emitting element of the first pixel and configured to convert light emitted from the light emitting element of the first pixel into light of a first wavelength band, a second light conversion layer on the light emitting element of the second pixel and configured to convert light emitted from the light emitting element of the second pixel into light of a second wavelength band, and a light transmitting layer on the light emitting element of the third pixel and configured to transmit light emitted from the light emitting element of the third pixel.

4. The display device of claim 1, further comprising:
a first scan line on the first island pattern, the second island pattern, and the first bridge pattern; and
a first scan pad connected to the first scan line and located on the first island pattern.

5. The display device of claim 4, wherein one of the plurality of pixel light emitting chips further comprises a first chip pad electrically connected to the first scan pad.

6. The display device of claim 5, wherein the first scan pad and the first chip pad overlap each other in a third direction, the third direction being a thickness direction of the substrate.

7. The display device of claim 5, wherein the transistor layer comprises:
a first insulating layer on the first chip pad;
a gate electrode of a first transistor from among the plurality of transistors on the first insulating layer and electrically connected to the first chip pad;
a second insulating layer on the gate electrode of the first transistor;
an active layer of the first transistor on the second insulating layer; and
a third insulating layer on the active layer of the first transistor.

8. The display device of claim 7, wherein the plurality of light emitting elements of the light emitting element layer are on the third insulating layer.

9. The display device of claim 1, further comprising:
a first data line on the first island pattern, the second island pattern, and the first bridge pattern; and
a first data pad connected to the first data line and located on the first island pattern.

10. The display device of claim 9, wherein one of the plurality of pixel light emitting chips further comprises a second chip pad electrically connected to the first data pad.

11. The display device of claim 10, wherein the first data pad and the second chip pad overlap each other in a third direction, the third direction being a thickness direction of the substrate.

12. The display device of claim 10, wherein the transistor layer comprises:
a first insulating layer on the second chip pad;
a gate electrode of a second transistor from among the plurality of transistors and a first connection electrode on the first insulating layer;
a second insulating layer on the first connection electrode and the gate electrode of the second transistor;
an active layer of the second transistor on the second insulating layer and connected to the first connection electrode through a contact hole penetrating the second insulating layer; and
a third insulating layer on the active layer of the second transistor.

13. The display device of claim 12, wherein the plurality of light emitting elements of the light emitting element layer are located on the third insulating layer.

14. The display device of claim 1, further comprising:
a first power line on the first island pattern, the second island pattern, and the first bridge pattern; and
a first power pad connected to the first power line and located on the first island pattern.

15. The display device of claim 14, wherein one of the plurality of pixel light emitting chips further comprises a third chip pad electrically connected to the first power pad.

16. The display device of claim 15, wherein the transistor layer comprises:
a first insulating layer on the third chip pad;
a second connection electrode on the first insulating layer and connected to the third chip pad through a contact hole penetrating the first insulating layer;
a second insulating layer on the second connection electrode; and
a third connection electrode on the second insulating layer and connected to the second connection electrode through a contact hole penetrating the second insulating layer.

17. The display device of claim 16, wherein each of the plurality of light emitting elements of the light emitting element layer comprises a first semiconductor layer, an active layer, and a second semiconductor layer sequentially stacked, and
wherein the third connection electrode is electrically connected to the second semiconductor layer.

18. A display device comprising:
a substrate comprising a first island pattern and a second island pattern adjacent to each other in a first direction, a third island pattern adjacent to the first island pattern in a second direction crossing the first direction, a first bridge pattern connecting the first island pattern and the second island pattern, and a second bridge pattern connecting the first island pattern and the third island pattern in the second direction;
a first scan line located on the first island pattern and the first bridge pattern, and configured to receive a first scan signal;
a first data line located on the first island pattern and the second bridge pattern, and configured to receive a first data voltage;
a first scan pad located on the first island pattern, and connected to the first scan line;
a first data pad located on the first island pattern, and connected to the first data line; and
a pixel light emitting chip comprising a pad layer comprising a first chip pad electrically connected to the first scan pad and a second chip pad electrically connected to the first data pad, a transistor layer comprising a plurality of transistors located on the pad layer, and a light emitting element layer located on the transistor layer and comprising a plurality of light emitting elements.

19. A method for fabricating a display device, comprising:
forming a plurality of pixel light emitting chips, each of the plurality of pixel light emitting chips comprising a chip pad layer comprising a plurality of chip pads, a transistor layer located on the chip pad layer, and a light emitting element layer located on the transistor layer;
forming a substrate comprising a plurality of island patterns and bridge patterns each connecting island patterns adjacent to each other from among the plurality of island patterns; and
attaching the plurality of pixel light emitting chips to the plurality of island patterns, respectively.

20. The method of claim 19, wherein the forming of the plurality of pixel light emitting chips comprises:
sequentially forming a second semiconductor material layer, an active material layer, and a first semiconductor material layer on a semiconductor substrate;
forming a first insulating layer on the first semiconductor material layer, and forming active patterns of transistors on the first insulating layer;
forming a second insulating layer on the active patterns, and forming gate electrodes of the transistors on the second insulating layer;
forming a third insulating layer on the gate electrodes, and forming the plurality of chip pads on the third insulating layer;
removing the semiconductor substrate; and
patterning the second semiconductor material layer, the active material layer, and the first semiconductor material layer to form the light emitting element layer comprising a plurality of light emitting elements.
